(19) United States
(12) Patent Application Publication
(10) Pub. No.: US 2025/0248044 A1
(43) Pub. Date: Jul. 31, 2025

(54) VERTICAL SEMICONDUCTOR DEVICE

(71) Applicant: Samsung Electronics Co., Ltd., Suwon-si (KR)

(72) Inventors: Minsoo Kim, Suwon-si (KR); Huijung Kim, Suwon-si (KR); Kiseok Lee, Suwon-si (KR); Yongkwan Kim, Suwon-si (KR); Dongoh Kim, Suwon-si (KR)

(21) Appl. No.: 18/966,251

(22) Filed: Dec. 3, 2024

(30) Foreign Application Priority Data
Jan. 26, 2024 (KR) 10-2024-0011988

(51) Int. Cl. H10B 51/20; H10B 51/10; H10B 51/30

(52) U.S. Cl. CPC H10B 51/20; H10B 51/30; H10B 51/10

(57) ABSTRACT

A vertical semiconductor device includes: a word line having a pillar shape on a substrate, the word line extending in a vertical direction perpendicular to an upper surface of the substrate; a ferroelectric layer pattern extending around a sidewall and bottom of the word line; a memory layer including an interface insulation layer pattern and a channel pattern sequentially stacked on the ferroelectric layer pattern, each of the interface insulation layer pattern and the channel pattern having a ring shape extending around the sidewall of the word line; a source line contacting a first portion of an outer wall of the channel pattern, the source line extending in a first direction parallel to the upper surface of the substrate; and a bit line extending in the first direction, the bit line contacting a second portion of the outer wall of the channel pattern facing the first portion.

### CROSS-REFERENCE TO RELATED APPLICATION(S)

This application claims priority under 35 USC § 119 to Korean Patent Application No. 10-2024-0011988, filed on Jan. 26, 2024, in the Korean Intellectual Property Office (KIPO), the contents of which are incorporated by reference herein in their entirety.

### BACKGROUND

The present inventive concept relates generally to a vertical semiconductor device, and, more particularly, relates to a vertical non-volatile memory device in which memory cells are stacked in a vertical direction.

For high integration of a semiconductor device, a vertical memory device in which memory cells are stacked in the vertical direction may be developed. Further, a structure including a ferroelectric material in the memory cells of the vertical memory device may be proposed.

### SUMMARY

Various example embodiments of the present disclosure provide a vertical semiconductor device including memory cells stacked in the vertical direction.

According to some example embodiments, there is provided a vertical semiconductor device. The vertical semiconductor device may include: a word line having a pillar shape on a substrate, the word line extending in a vertical direction perpendicular to an upper surface of the substrate; a ferroelectric layer pattern surrounding a sidewall and bottom of the word line; a memory layer including an interface insulation layer pattern and a channel pattern stacked on the ferroelectric layer pattern, each of the interface insulation layer pattern and the channel pattern having a ring shape surrounding the sidewall of the word line; a source line contacting a first portion of an outer wall of the channel pattern, the source line extending in a first direction parallel to the upper surface of the substrate; and a bit line extending in the first direction, the bit line contacting a second portion facing the first portion of the outer wall of the channel pattern.

According to some example embodiments, there is provided a vertical semiconductor device. The vertical semiconductor device may include: a mold layer pattern on a substrate; a plurality of word lines passing through the mold layer pattern, each of the word lines having a pillar shape extending in a vertical direction perpendicular to the upper surface of the substrate, and being arranged in each of a first direction and a second direction parallel to the upper surface of the substrate and perpendicular to each other; a ferroelectric layer pattern surrounding (i.e., extending around) a sidewall and bottom of each of the word lines; a plurality of memory layers on the ferroelectric layer pattern, each of the memory layers including an interface insulation layer pattern and a channel pattern having a ring shape surrounding a sidewall of each of the word lines, and the memory layers being spaced apart from each other in the vertical direction; a plurality of bit lines being spaced apart in the vertical direction, each of the bit lines being electrically connected to the channel patterns at each of vertical levels included in the memory layers, and being electrically connected to the channel patterns arranged in the first direction; and a source line extending in the vertical direction, the source line being commonly connected to channel patterns included in the memory layers arranged in the vertical direction, and being electrically connected to channel patterns arranged in the first direction, and the source line disposed to face the bit lines in the second direction.

According to some example embodiments, there is provided a vertical semiconductor device. The vertical semiconductor device may include: a word line having a pillar shape on a substrate; a memory layer including a ferroelectric layer pattern, an interface insulation layer, and a channel pattern sequentially stacked on an outer wall of the word line; a bit line extending in a horizontal direction parallel an upper surface of the substrate while contacting an outer wall of the channel pattern; a source line contacting the outer wall of the channel pattern, the source line extending in the horizontal direction, and the source line disposed to face the bit lines in the second direction.

According to example embodiments, the memory cells may be stacked in the vertical direction, so that the vertical semiconductor device including the memory cells may have high integration. Additionally, each of the memory cells may include a ferroelectric layer pattern, so that the vertical semiconductor device including the memory cells may have a simple stacked structure and excellent operating characteristics.

### BRIEF DESCRIPTION OF THE DRAWINGS

Various example embodiments will be more clearly understood from the following detailed description taken in conjunction with the accompanying drawings, wherein like reference numerals (when used) indicate corresponding elements throughout the several views. FIGS. 1 to 41 represent various non-limiting, example embodiments as described herein.

FIG. 1 is a plan view schematically illustrating a vertical semiconductor device according to example embodiments;

FIGS. 2A and 2B are schematic cross-sectional views of a vertical semiconductor device according to example embodiments;

FIG. 3 is a perspective view schematically illustrating a unit memory cell of a vertical semiconductor device according to example embodiments;

FIG. 4 is an equivalent circuit diagram of a vertical semiconductor device according to example embodiments;

FIG. 5 is a schematic cross-sectional view of a vertical semiconductor device according to some example embodiments;

FIG. 6 is a cross-sectional view schematically illustrating a vertical semiconductor device according to some example embodiments;

FIG. 7 is a cross-sectional view illustrating a vertical semiconductor device according to some example embodiments;

FIG. 8 is a plan view schematically illustrating a vertical semiconductor device according to example embodiments;

FIG. 9 is a schematic cross-sectional view of a vertical semiconductor device according to example embodiments;

FIG. 10 is a perspective view schematically illustrating a unit memory cell in a vertical semiconductor device according to example embodiments;

FIGS. 11 to 35 are plan views and cross-sectional views schematically illustrating intermediate processes in an example method of manufacturing a vertical semiconductor device according to one or more embodiments;

FIG. 36 is a graph showing an operation of the memory cell of the vertical semiconductor device according to one or more embodiments;

FIG. 37 is a plan view schematically illustrating wiring connected to the word lines in the vertical semiconductor device according to example embodiments;

FIGS. 38 and 39 are a plan view and a cross-sectional view, respectively, schematically illustrating an end of the bit line and a shape of a wiring in the vertical semiconductor device according to example embodiments;

FIG. 40 is a cross-sectional view schematically illustrating an arrangement of peripheral circuits in a vertical semiconductor device according to example embodiments; and

FIG. 41 is a cross-sectional view schematically illustrating an arrangement of peripheral circuits in a vertical semiconductor device according to example embodiments.

### DETAILED DESCRIPTION

Hereinafter, various example embodiments will be described in detail with reference to the accompanying drawings. In the following description, directions parallel to a surface of a substrate and intersecting (e.g., perpendicular to) each other are referred to as a first direction and a second direction, respectively, which are horizontal directions. Additionally, a direction perpendicular to the surface of the substrate surface is referred to as a vertical direction.

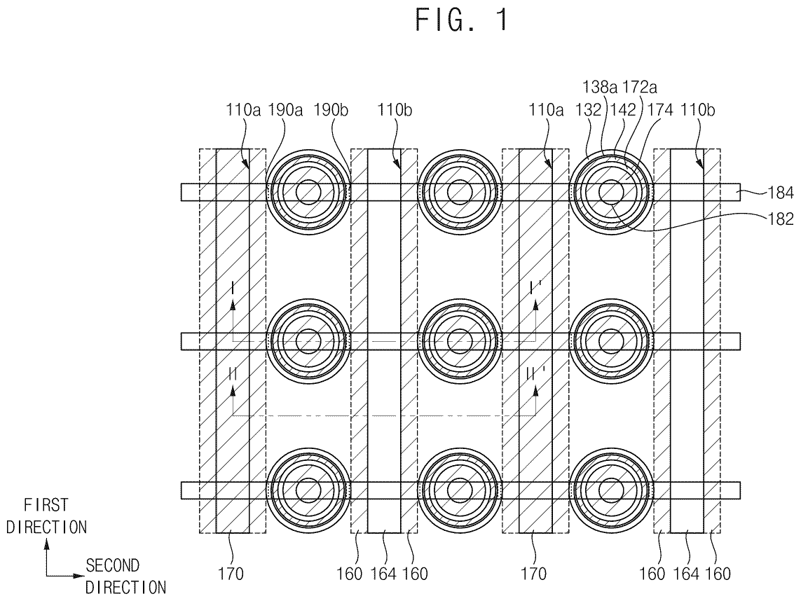

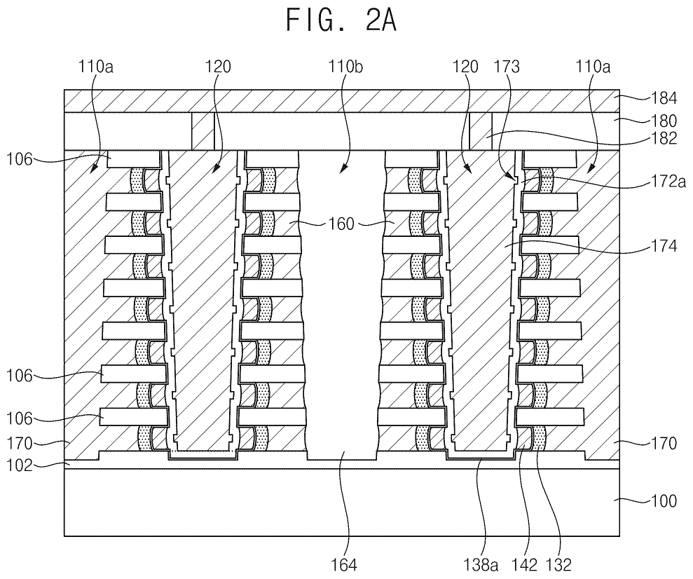

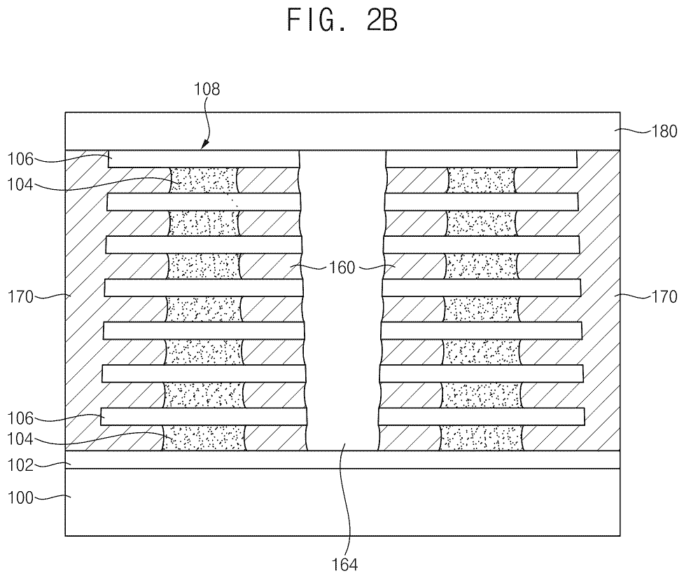

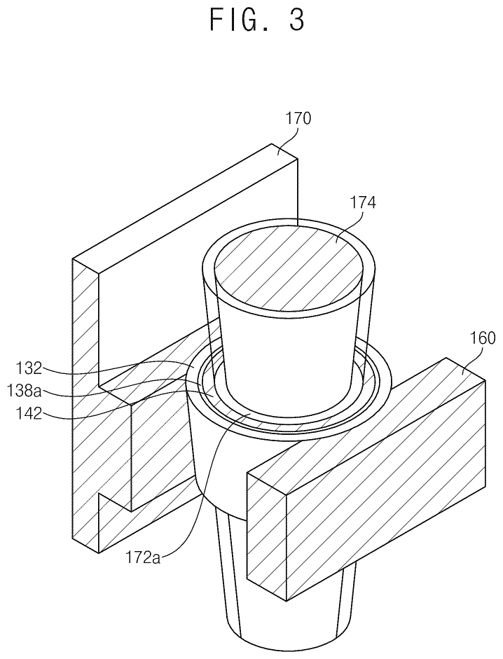

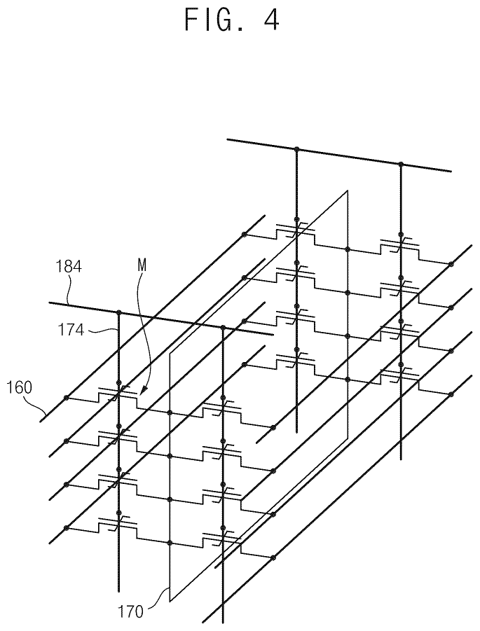

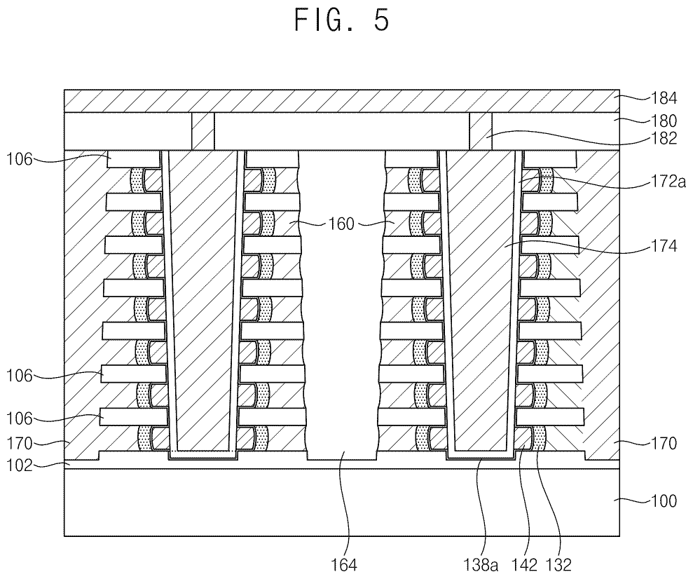

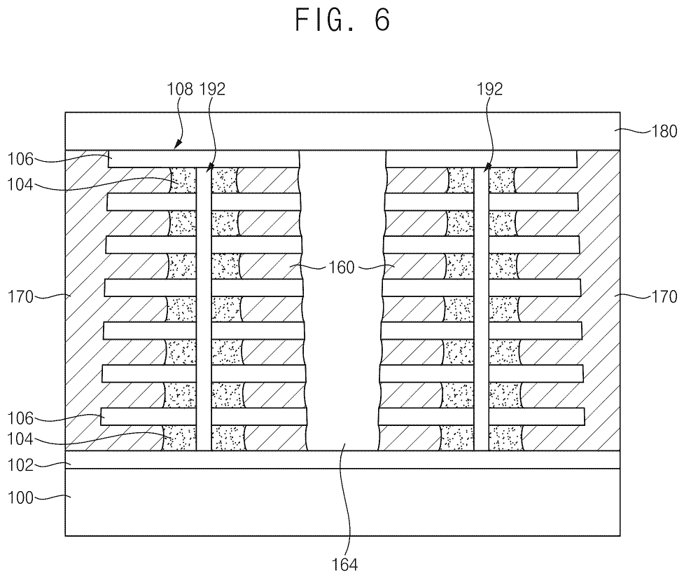

FIG. 1 is a plan view schematically illustrating a vertical semiconductor device according to example embodiments. FIGS. 2A and 2B are schematic cross-sectional views of a vertical semiconductor device according to example embodiments. FIG. 3 is a perspective view schematically illustrating a unit memory cell of a vertical semiconductor device according to example embodiments. FIG. 4 is an equivalent circuit diagram of a vertical semiconductor device according to example embodiments. FIG. 5 is a schematic cross-sectional view of a vertical semiconductor device according to some example embodiments. FIG. 6 is a cross-sectional view schematically illustrating a vertical semiconductor device according to some example embodiments. FIG. 7 is a cross-sectional view schematically illustrating a vertical semiconductor device according to some example embodiments.

FIG. 2A is a cross-sectional view taken along line I-I′ of FIG. 1, and FIG. 2B is a cross-sectional view taken along line II-II′ of FIG. 1. FIGS. 5 and 7 are cross-sectional views taken along line I-I′ of FIG. 1. FIG. 6 is a cross-sectional view taken along line II-II′ of FIG. 1.

Referring to FIGS. 1, 2A, and 2B, a vertical semiconductor device may be formed on a substrate 100. The substrate 100 may include a semiconductor material such as silicon, germanium, or silicon-germanium, or a group III-V compound such as GaP, GaAs, or GaSb. In some example embodiments, the substrate 100 may be a silicon-on-insulator (SOI) substrate or a germanium-on-insulator (GOI) substrate.

A lower etch stop layer 102 may be on the substrate 100. A first mold layer pattern 108 in which first sacrificial layers 104 and first insulation layers 106 are alternately stacked in a vertical direction may be disposed on the lower etch stop layer 102. One of the first insulation layers 106 may be disposed at an uppermost surface of the first mold layer pattern 108.

The lower etch stop layer 102 may include an insulation material. The lower etch stop layer 102 may include a material having an etch selectivity with respect to a material of the first sacrificial layer 104. The lower etch stop layer 102 may include, e.g., silicon oxide.

The first insulation layer 106 may include, e.g., silicon oxide. The first sacrificial layer 104 may include a material having an etch selectivity with respect to a material of the first insulation layer 106. The first sacrificial layer 104 may include, e.g., silicon nitride. In example embodiments, the first sacrificial layer 104 may include the silicon nitride including at least one of carbon, nitrogen, oxygen, and boron, although embodiments are not limited thereto.

The first mold layer pattern 108 may extend in the first direction. A plurality of first mold layer patterns 108 may be spaced apart from each other in the second direction intersecting the first direction.

First and second trenches 110a and 110b may be disposed between the first mold layer patterns 108 in the second direction. A side of the first trench 110a may correspond to a first sidewall of the first mold layer pattern 108, and a side of the second trench 110a may correspond to a second sidewall facing the first sidewall of the first mold layer pattern 108. The lower etch stop layer 102 may be exposed by a bottom of the first and second trenches 110a and 110b. The first mold layer patterns 108 may be separated by the first and second trenches 110a and 110b.

The first and second trenches 110a and 110b may extend in the first direction. The first and second trenches 110a and 110b may be arranged in parallel, and may be spaced apart from each other in the second direction. The first and second trenches 110a and 110b may be alternately arranged.

First holes 120 may extend from an upper surface of the first mold layer pattern 108 to the lower etch stop layer 102 in the vertical direction. In example embodiments, the first holes 120 may be spaced apart in each of the first direction and the second direction. The first holes 120 may be aligned in each of the first direction and the second direction (i.e., arranged in columns and rows).

In some example embodiments, at least a portion of the first mold layer pattern 108 may be replaced with air. In some example embodiments, as shown in FIG. 6, the first mold layer pattern 108 may include an air tunnel 192 or a void therein. A space between adjacent channel patterns 132 in the first direction may include air, so that a parasitic capacitance between the channel patterns 132 may be decreased. In some example embodiments, the first mold layer pattern 108 may not be formed, and a low dielectric layer pattern including an insulation material having a low dielectric constant may be formed instead of the first mold layer pattern 108.

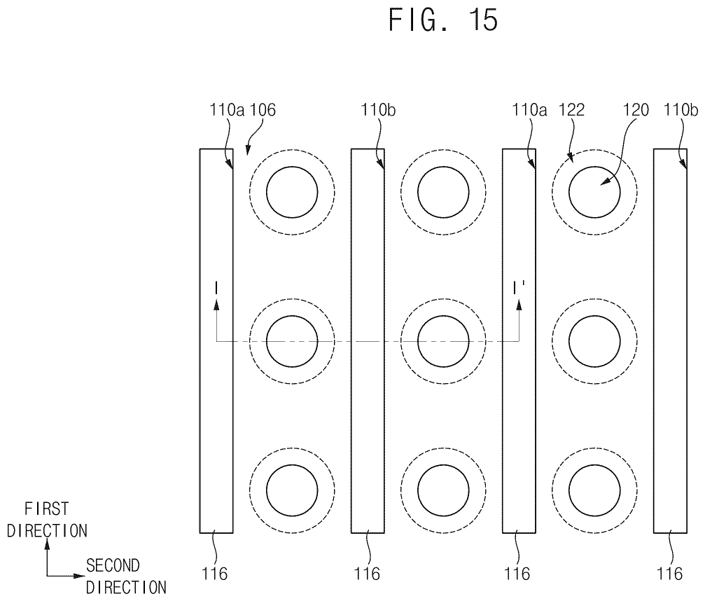

The first insulation layers 106 may be exposed by the sidewall of the first hole 120. First recesses 122 (see FIG. 16) formed by partially removing the first sacrificial layers 104 may be disposed at the sidewall of the first holes. The first insulation layers 106 exposed by the sidewall of the first hole 120 may laterally protrude from sidewalls of the first recesses 122. Each of the first recesses 122 may be disposed between the first insulation layers 106 in the vertical direction. The first recesses 122 may be laterally connected with the first hole 120, and each of the first recesses 122 may have a ring shape surrounding the first hole 120. The term “surrounding” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles.

A channel pattern 132, an interface insulation layer pattern 138a and a floating gate electrode 142 may be sequentially and laterally stacked in each of the first recesses 122. First memory layers including the channel pattern 132, the interface insulation layer pattern 138a, and the floating gate electrode 142 may be spaced apart from each other in the vertical direction. The first insulation layer 106 may be interposed between the first memory layers stacked in the vertical direction, and the first memory layers may be insulated from each other by the first insulation layer 106.

The channel pattern 132, the interface insulation layer pattern 138a, and the floating gate electrode 142 disposed in each of vertical levels may have a ring shape. The first memory layer may have a ring shape.

In example embodiments, the floating gate electrode 142 may be in the first recess 122. That is, a sidewall of the floating gate electrode 142 may not laterally protrude from the sidewall of the first insulation layer 106.

In example embodiments, the channel pattern 132 may include polysilicon, an oxide semiconductor, or a two-dimensional material. The oxide semiconductor may include, e.g., InxGayZnzO, InxSnyZnzO, InxZnyO, ZnxO, ZnxSnyO, ZnxOyN, ZrxZnySnzO, HfxInyZnzO, GaxZnySnzO, AlxZnySnzO, YbxGayZnzO, or a combination thereof. The two-dimensional material may include, e.g., MoS2, MoSe2, or WS2.

The interface insulation layer pattern 138a may include, e.g., silicon oxide or metal oxide. In example embodiments, the floating gate electrode 142 may include metal or polysilicon.

A ferroelectric layer pattern 172a may be formed on surfaces of the first insulation layers 106 and floating gate electrodes 142 exposed by a sidewall of the first hole 120 and the lower etch stop layer 102 exposed by a bottom of the first hole 120. The ferroelectric layer pattern 172a may be continuously and conformally disposed on the surfaces of the first insulation layers 106, the floating gate electrodes 142, and the lower etch stop layer 102.

In example embodiments, as shown in FIG. 2A, one sidewall of the ferroelectric layer pattern 172a may include grooves 173 at portions facing the first recesses 122 (i.e., horizontally overlapping the first recesses 122). In some example embodiments, as shown in FIG. 5, one sidewall of the ferroelectric layer pattern 172a may not include the grooves 173 at the portions facing the first recesses 122.

In example embodiments, the ferroelectric layer pattern 172a may include a hafnium oxide layer, a zirconium oxide layer, or a hafnium zirconium oxide layer.

In example embodiments, the ferroelectric layer pattern 172a may have an orthorhombic phase. In some example embodiments, the ferroelectric layer pattern 172a may have a tetragonal phase with anti-ferroelectric properties.

The ferroelectric layer pattern 172a may further include dopants therein, and the dopants may include, e.g., silicon (Si), zirconium (Zr), aluminum (Al), yttrium (Y), lanthanum (La), carbon (C), nitrogen (N), germanium (Ge), tin (Sn), strontium (Sr), lead (Pb), calcium (Ca), barium (Ba), titanium (Ti), zirconium (Zr), or gadolinium (Gd), etc.

In example embodiments, a dielectric layer may be further formed on, below, or inside the ferroelectric layer pattern 172a to form a ferroelectric layer structure having a multi-layer structure. When the ferroelectric layer structure may include the dielectric layer, the dielectric layer may supply tensile stress or compressive stress to the ferroelectric layer. Thus, the dielectric layer may promote the ferroelectric layer to have an orthorhombic phase or tetragonal phase and induce stabilization of the crystal phase of the ferroelectric layer. Accordingly, a durability of the ferroelectric layer pattern 172a may be improved, and thus operating characteristics of the semiconductor device, such as data retention and memory window (i.e., data sensing margin), may be improved.

In some example embodiments, the ferroelectric layer pattern 172a may include a ferroelectric material having a perovskite structure. For example, the ferroelectric layer pattern 172a may include SrBi2Ta2O9, (Bi,La)4Ti3O12, or (Pb,Zr)TiO3.

A word line 174 may be on the ferroelectric layer pattern 172a to fill the first hole 120. The term “fill” (or “filling,” “filled,” or like terms), as may be used herein, is intended to refer broadly to either completely filling a defined space (e.g., the first hole 120) or partially filling the defined space; that is, the defined space need not be entirely filled but may, for example, be partially filled or have voids or other spaces throughout. The word line 174 may serve as a gate electrode.

In example embodiments, the word line 174 may pass through the first mold layer pattern 108. In example embodiments, the first mold layer pattern 108 may be disposed between word lines 174 in the first direction.

A plurality of word lines 174 may be spaced apart from each other in the first direction. Further, the word lines 174 may be spaced apart from each other in the second direction. The word lines 174 may be aligned in each of the first and second directions.

The word line 174 may include, e.g., metal. The word line 174 may have a pillar shape extending in the vertical direction.

A sidewall of the word line 174 may horizontally face the channel pattern 132, the interface insulation layer pattern 138a, the floating gate electrode 142, and the ferroelectric layer pattern 172a disposed in each of vertical levels. The channel pattern 132, the interface insulation layer pattern 138a, and the floating gate electrode 142 disposed at each of a plurality of different vertical levels, relative to an upper surface of the substrate 100 as a reference layer, may have a ring shape surrounding the sidewall of the word line 174. The ferroelectric layer pattern 172a may surround the sidewall and bottom of the word line 174.

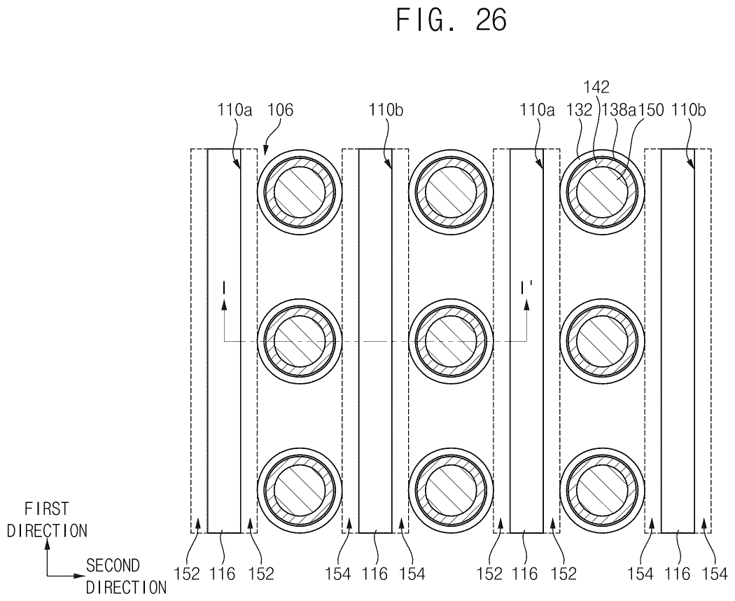

The first insulation layers 106 may be exposed by both sidewalls of the first trench 110a. Additionally, second recesses 152 (referred to FIG. 27) formed by partially removing the first sacrificial layers 104 may be disposed at both sidewalls of the first trench 110a. Each of the second recesses 152 may be disposed between the first insulation layers 106 in the vertical direction. The second recesses 152 may be laterally connected with the first trench 110a, and each of the second recesses 152 may extend in the first direction.

A source line 170 may at least partially fill each of the second recesses 152 and the first trench 110a. The source line 170 may include, e.g., a metal.

In example embodiments, the source line 170 may include a single metal. That is, the source line 170 may include one conductive pattern. In some example embodiments, the source line 170 may include a plurality of conductive patterns. The source line 170 may include a plurality of metals.

The source line 170 may extend in the vertical direction from the lower etch stop layer 102. The source line 170 may extend in the first direction.

The source line 170 may contact first portions of outer walls of the channel patterns 132 at each of a plurality of different vertical levels relative to the upper surface of the substrate 100. The first portion of the channel pattern 132 may be doped with N-type impurities or P-type impurities. A first impurity region 190a may be formed in the first portion of the channel pattern 132.

The source line 170 may extend in the first direction while contacting the first portions of the outer walls of the channel patterns 132 spaced apart from each other in the first direction.

The source line 170 may contact the channel patterns 132 on both sidewalls of the first trench 110a. Thus, the source line 170 may be electrically connected to a pair of adjacent channel patterns 132 in the second direction, respectively.

Accordingly, the source line 170 may be electrically connected to the channel patterns 132 disposed at different vertical levels and the channel patterns 132 spaced apart from each other in the first direction. Additionally, the source line 170 may be electrically connected to a pair of adjacent channel patterns 132 in the second direction. The source line 170 may be electrically connected to the channel patterns 132 on the word lines 174 arranged in the first direction, and may contact outer walls of the channel patterns 132 disposed on a pair of adjacent word lines 174 in the second direction. Accordingly, the source line 170 may serve as a common source of each of the memory cells formed on the channel patterns 132.

In example embodiments, all channel patterns 132 disposed between the second trenches 110b may be electrically connected to the source line 170 disposed between the second trenches 110b.

The first insulation layers 106 may be exposed by both sidewalls of the second trench 110b. Third recesses 154 (see FIG. 27) formed by partially removing the first sacrificial layers 104 may be disposed at both sidewalls of the second trench 110b. Each of the third recesses 154 may be disposed between the first insulation layers 106 in the vertical direction. The third recesses 154 may be laterally connected with the second trench 110b, and each of the third recesses 154 may extend in the first direction.

A bit line 160 may be disposed in each of the third recesses 154. The bit line 160 may extend in the first direction, and may contact second portions of the outer walls of the channel patterns 132. The second portion of the channel pattern 132 may face the first portion of the channel pattern 132 in the second direction. The second portion of the channel pattern 132 may be doped with N-type impurities or P-type impurities. A second impurity region 190b may be formed in the second portion of the channel pattern 132. The bit line 160 may include, e.g., metal.

The bit lines 160 may be spaced apart from each other in the vertical direction, so that the bit lines 160 may be disposed at each of a plurality of different vertical levels relative to the upper surface of the substrate 100. The first insulation layer 106 may be interposed between the bit lines 160 in the vertical direction. Accordingly, the bit lines 160 disposed in the vertical direction may be insulated by the first insulation layer 106. In example embodiments, each of the bit lines 160 may be electrically connected to the channel pattern 132 disposed at each of the plurality of different vertical levels.

The bit lines 160 may be disposed on both sidewalls of the second trench 110b, respectively. A pair of bit lines 160 facing in a horizontal direction to each other may be disposed in the second trench 110b. The pair of bit lines 160 may be disposed between a pair of adjacent source lines 170 in the second direction.

The bit line 160 may extend in the first direction while electrically connecting the channel patterns 132 spaced apart from each other in the first direction disposed at the same vertical level relative to the upper surface of the substrate 100. The bit line 160 may be electrically connected to the channel patterns on the word lines arranged in the first direction. The bit line 160 may not be connected to the channel patterns 132 spaced apart from each other in the second direction.

A first insulation structure 164 may at least partially fill the second trench 110b. The first insulation structure 164 may be disposed between the bit lines 160 in the second direction. The bit lines 160 disposed on both sidewalls of the second trench 110b may be insulated by the first insulation structure 164.

The first insulation structure 164 may extend in the first direction. Additionally, the first insulation structure 164 may extend in the vertical direction, and may contact the lower etch stop layer 102.

In example embodiments, the first insulation structure 164 may include silicon oxide or a dielectric insulation material having a dielectric constant lower than a dielectric constant of the silicon oxide.

In some example embodiments, the first insulation structure may not be formed, and the first insulation structure portion may be replaced by air (i.e., a gap or void). In some example embodiments, as shown in FIG. 7, an air tunnel 194 or a void may be formed in the first insulation structure 164. The air may be between the bit lines 160, so that a parasitic capacitance between the bit lines 160 may be decreased.

A first upper insulating interlayer 180 may be formed on the word line 174, the ferroelectric layer pattern 172a, the mold layer pattern 108, the source line 170, and the first insulation structure 164.

A contact plug 182 may pass through the first upper insulating interlayer 180, and may contact an upper surface of the word line 174. A first conductive line 184 extending in the second direction may be on the first upper insulating interlayer 180 and the contact plug 182.

The first conductive line 184 may be electrically connected to the plurality of word lines 174 arranged in the second direction via the contact plug 182. The word lines 174 may be spaced apart from each other in the first and second directions.

In example embodiments, each of first conductive lines 184 may be disposed on the word line column in which the word lines are arranged in the second direction. Accordingly, each of the first conductive line 184 may be electrically connected to all word lines 174 arranged in the second direction.

Each of the unit memory cells in the vertical memory device may have the following configuration.

Referring to FIG. 3, each of the unit memory cells may include the word line 174, the ferroelectric layer pattern 172a, the floating gate electrode 142, the interface insulation layer pattern 138a, and the channel pattern 132. The ferroelectric layer pattern 172a, the floating gate electrode 142, the interface insulation layer pattern 138a, and the channel pattern 132 may be formed as stacked concentric rings extending around the word line 174. The channel pattern 132 may be connected to the bit line 160 and the source line 170. In example embodiments, each of the unit memory cells may have an MFMIS structure, which is metal/ferroelectric/metal/insulator/silicon stacked structure.

The word line 174 may have a pillar shape. The ferroelectric layer pattern 172a, the floating gate electrode 142, the interface insulation layer pattern 138a, and the channel pattern 132 may be sequentially disposed on the outer surface of the word line 174. The ferroelectric layer pattern 172a, the floating gate electrode 142, the interface insulation layer pattern 138a, and the channel pattern 132 may surround the sidewall of the word line 174. The floating gate electrode 142, the interface insulation layer pattern 138a, and the channel pattern 132 may have a ring shape surrounding the sidewall of the word line 174.

The bit line 160 and the source line 170 may face each other in the second direction with the channel pattern 132 interposed therebetween. The source line 170 may contact the first portions of the outer walls of the channel patterns 132. The bit line 160 may contact the second portions of the outer walls of the channel patterns 132.

Each of the unit memory cells in the vertical memory device may be electrically connected to the bit line 160 and source line 170.

Referring to FIG. 4, the memory layer disposed at each of the plurality of different vertical levels and the ferroelectric layer pattern contacting the memory layer may serve as a memory structure M constituting the unit memory cell.

The source line 170 may be electrically connected to the channel patterns 132 (see FIG. 3) included in the memory structures M stacked in the vertical direction, the channel patterns 132 included in the memory structures spaced apart from each other in the first direction, and the channel patterns 132 included in adjacent two memory structures M in the second direction.

The bit line 160 may be electrically connected to the channel patterns 132 included in the memory structure M disposed at each of the vertical levels and the channel patterns 132 included in the memory structure M spaced apart in the first direction at the same vertical level.

The word line 174 may contact the ferroelectric layer patterns (172a in FIG. 3) included in the memory structures M stacked in the vertical direction, so that the word line 174 may be electrically connected to the memory structures M.

In example embodiments, the unit memory cell of the vertical semiconductor device may be a 1T DRAM cell including one transistor.

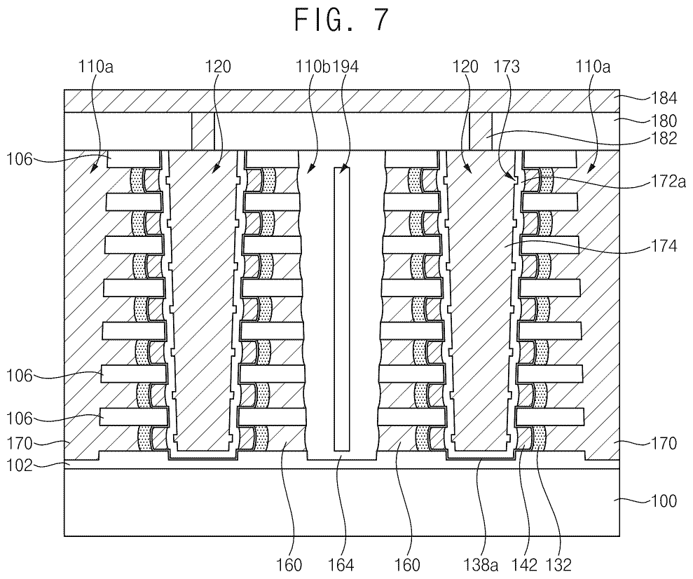

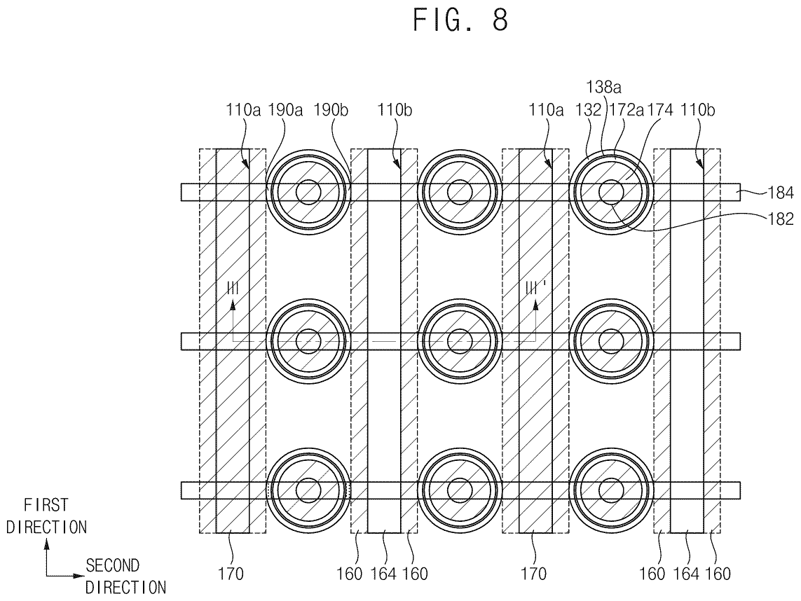

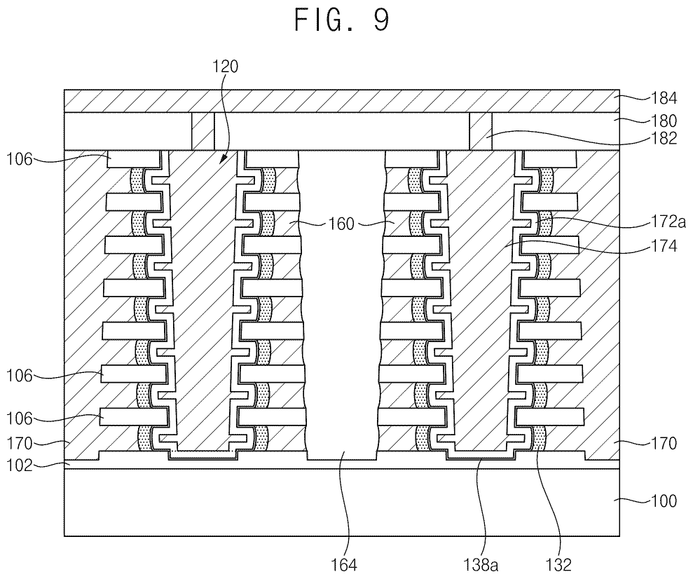

FIG. 8 is a plan view schematically illustrating a vertical semiconductor device according to example embodiments. FIG. 9 is a schematic cross-sectional view of a vertical semiconductor device according to example embodiments. FIG. 10 is a perspective view schematically illustrating a unit memory cell in a vertical semiconductor device according to example embodiments.

The vertical memory device as shown in FIGS. 8 to 10 may be the same as the vertical semiconductor device described with reference to FIGS. 1 to 7, except for a stacked structure of the unit memory cell. Therefore, repeated explanations may be omitted.

FIG. 9 is a cross-sectional view taken along line III-III′ of FIG. 8.

Referring to FIGS. 8 and 9, the channel pattern 132 and the interface insulation layer pattern 138a may be laterally stacked in each of the first recesses disposed at the sidewall of the first hole 120. A floating gate electrode (e.g., 142 in FIGS. 1 and 2A) may not be formed on the interface insulation layer pattern 138a. The first memory layer may include only the channel pattern 132 and the interface insulation layer pattern 138a.

The first memory layers may be spaced apart from each other in the vertical direction, and the first memory layers may be at each of a plurality of different vertical levels relative to the upper surface of the substrate 100 as a reference layer. The first memory layers may be insulated by the first insulation layer 106.

Each channel pattern 132 and the interface insulation layer pattern 138a disposed at each of the vertical levels may have a ring shape. The first memory layer may have a ring shape.

A ferroelectric layer pattern 172a may be disposed on surfaces of the first insulation layers 106 and the interface insulation layer pattern 138a exposed by the sidewall of the first hole 120 and the lower etch stop layer 102 at a bottom of the first hole. The ferroelectric layer pattern 172a may be continuously and conformally formed on the surfaces of the first insulation layers 106, the interface insulation layer patterns 138a, and the lower etch stop layer 102. The ferroelectric layer pattern 172a may surround a sidewall and bottom of the word line 174.

In example embodiments, as shown in FIG. 9, one sidewall of the ferroelectric layer pattern 172a may include grooves 173 (see FIGS. 2A and 7) at portions facing the first recesses 122 (referred to FIG. 16). In some example embodiments, one sidewall of the ferroelectric layer pattern 172a may not include the grooves at the portions facing the first recesses 122.

Each of unit memory cells in the vertical memory device may have the following configuration.

Referring to FIG. 10, each of the unit memory cells may include the word line 174, the ferroelectric layer pattern 172a, the interface insulation layer pattern 138a, and the channel pattern 132. Additionally, the channel pattern 132 may be connected to the bit line 160 and the source line 170. In example embodiments, each of the unit memory cells may have an MFIS structure, which is a metal/ferroelectric/insulator/silicon stacked structure.

The word line 174 may have a pillar shape. The ferroelectric layer pattern 172a, the interface insulation layer pattern 138a, and the channel pattern 132 may be sequentially disposed on an outer surface of the word line 174. The ferroelectric layer pattern 172a, the interface insulation layer pattern 138a, and the channel pattern 132 may surround the sidewall of the word line 174. Each of the interface insulation pattern 138a and the channel pattern 132 may have a concentric ring shape surrounding the sidewall of the word line 174.

The bit line 160 and the source line 170 may face each other with the channel pattern 132 interposed therebetween. The bit line 160 may extend in the first direction while contacting the second portions of the outer walls of the channel patterns 132. The source line 170 may contact the first portions of the outer walls of the channel patterns 132. The source line 170 may extend in the first direction.

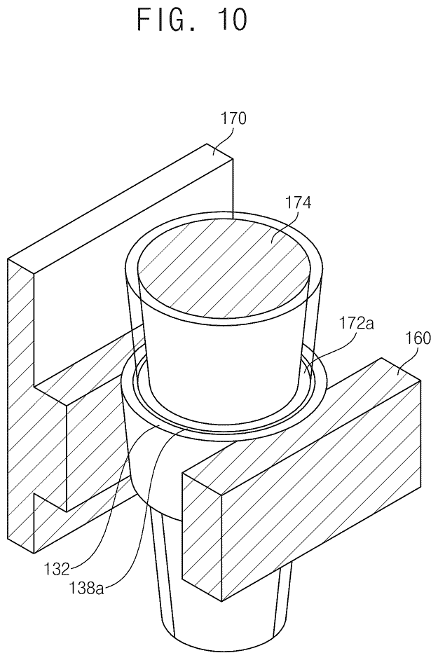

FIGS. 11 to 35 are plan views and cross-sectional views schematically illustrating intermediate processes in an example method of manufacturing a vertical semiconductor device according to one or more embodiments.

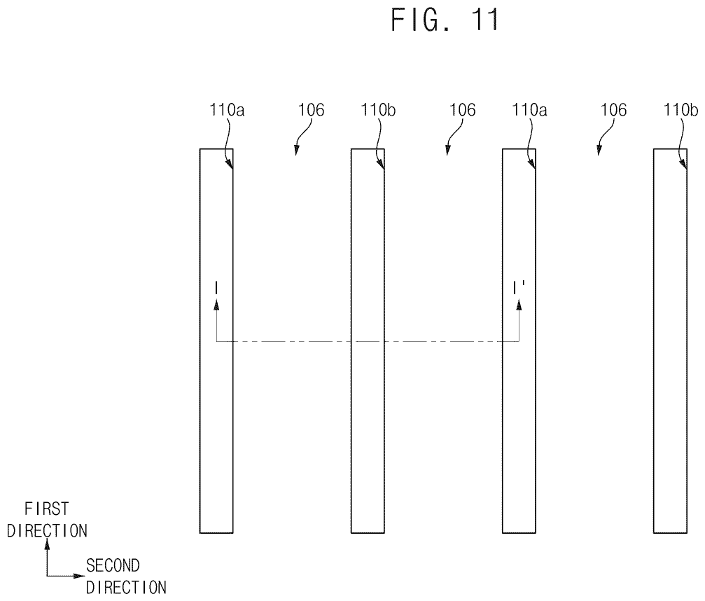

FIGS. 11, 13, 15, 18, 22, 24, 26, 28, 30, 32 and 34 are plan views. FIGS. 12, 14, 16, 17, 19, 20, 21, 23, 25, 27, 29, 31, 33 and 35 are cross-sectional views. Each of the cross-sectional views is a view taken along line I-I′ of the corresponding plan view.

Referring to FIGS. 11 and 12, a lower etch stop layer 102 may be formed on a substrate 100. First sacrificial layers 104 and first insulation layers 106 may be alternately and repeatedly formed on the lower etch stop layer 102, stacked in the vertical direction, to form a mold layer. One of the first insulation layers 106 may be formed at an uppermost of the mold layer.

The lower etch stop layer 102 may include an insulation material. The lower etch stop layer 102 may include a material having an etch selectivity with a material of the first sacrificial layer 104. The lower etch stop layer 102 may include, e.g., silicon oxide.

The first insulation layer 106 may include, e.g., silicon oxide. The first sacrificial layer 104 may include a material having an etch selectivity with respect to the first insulation layer 106. The first sacrificial layer 104 may include, e.g., silicon nitride. In example embodiments, the first sacrificial layer 104 may include a silicon nitride including least one of carbon, nitrogen, oxygen, and boron.

The number of stacks of the first insulation layer 106 and the first sacrificial layer 104 may not be limited. In example embodiments, the first sacrificial layer 104 may be replaced into a word line by subsequent processes, so that the number of stacks of the first sacrificial layer 104 may be equal to the number of memory cells vertically stacked.

In example embodiments, a cross-sectional thickness (i.e., in the vertical direction) of an uppermost first insulation layer 106 may be greater than a cross-sectional thickness of each of the first insulation layers 106 below the uppermost first insulation layer 106.

The first insulation layers 106 and the first sacrificial layers 104 may be etched to form first trenches 110a and second trenches 110b. The first and second trenches 110a and 110b may pass through the mold layer, and may expose an upper surface of the lower etch stop layer 102 proximate a bottom of each of the first and second trenches 110a, 110b. The etching process of the first insulation layers 106 and the first sacrificial layers 104 may include, e.g., a dry etching process.

The first and second trenches 110a and 110b may extend in the first direction. The first and second trenches 110a and 110b may be spaced apart from each other in the second direction. The first and second trenches 110a and 110b may be alternately arranged in the second direction.

Through subsequent processes, one source line 170 may be formed in the first trench 110a, and two bit lines 160 spaced apart from each other may be formed in the second trench 110b. The mold layers may be separated from each other by the first and second trenches 110a and 110b to form a first mold layer pattern 108 extending in the first direction. Memory cells may be formed in the first mold layer pattern 108 between the first trench 110a and the second trench 110b through the subsequent processes.

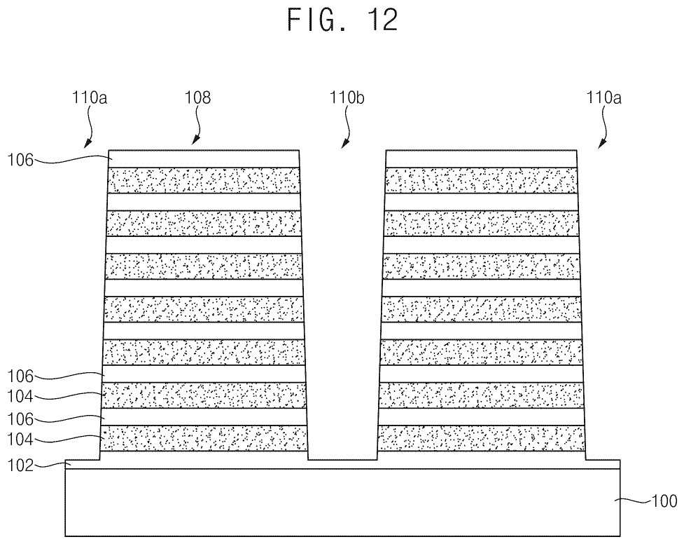

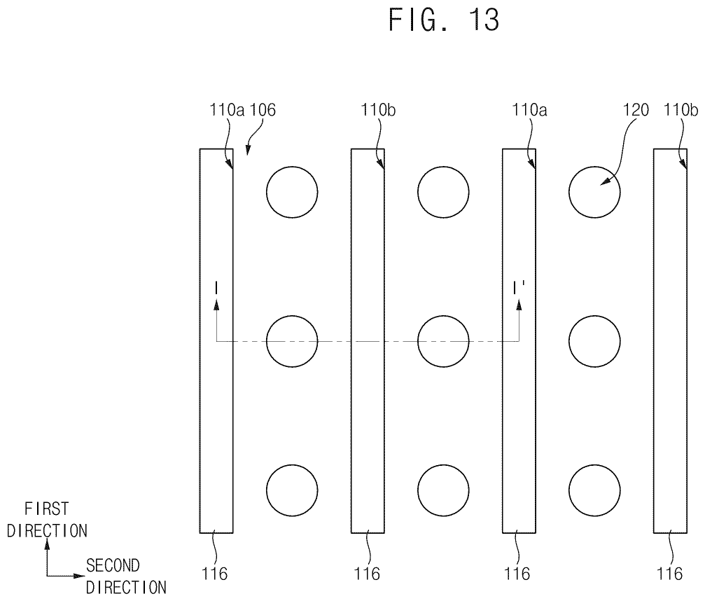

Referring to FIGS. 13 and 14, a first sacrificial layer structure 116 may be formed to at least partially fill the first and second trenches 110a and 110b.

In example embodiments, a liner sacrificial layer may be formed on inner surfaces of the first and second trenches 110a and 110b and the first mold layer pattern 108, and a second sacrificial layer may be formed on the liner sacrificial layer to at least partially fill the first and second trenches 110a and 110b, respectively. Upper portions of the liner sacrificial layer and the second sacrificial layer may be planarized until an upper surface of the first mold layer pattern 108 is exposed to form the first sacrificial layer structure 116 including a liner sacrificial layer pattern 112 and a second sacrificial layer pattern 114. The liner sacrificial layer pattern 112 may include, e.g., silicon nitride, and the second sacrificial layer pattern 114 may include, e.g., silicon oxide.

Thereafter, first holes 120 may be formed through the first mold layer pattern 108. The first holes 120 may expose the upper surface of the lower etch stop layer 102. In example embodiments, the first holes 120 may be spaced apart from each other in the first direction. The first holes 120 may be aligned in each of the first and second directions.

First insulation layers 106 and first sacrificial layers 104 included in the first mold layer pattern 108 may be exposed by sidewalls of each of the first holes 120.

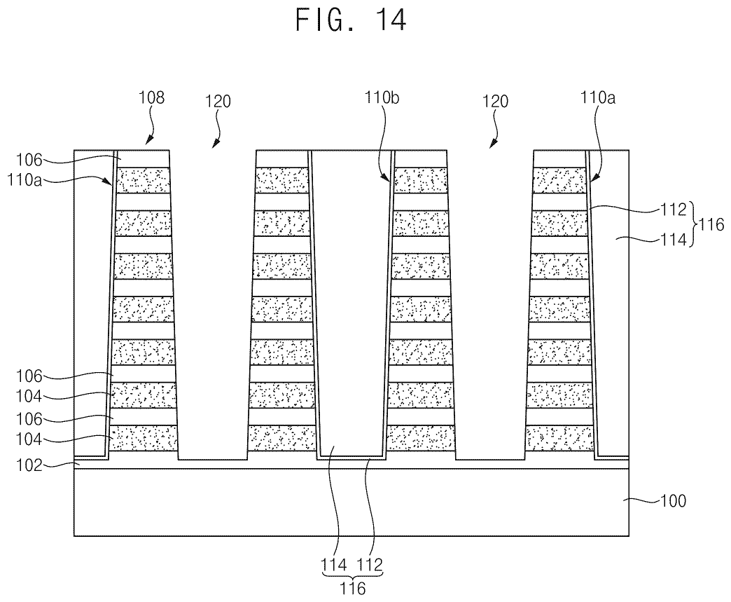

Referring to FIGS. 15 and 16, the first sacrificial layers 104 exposed by the sidewalls of the first holes 120 may be partially isotropically etched to form first recesses 122 being connected with the first holes 120 in a lateral direction.

The first recesses 122 may be spaced apart from each other in the vertical direction. The first insulation layer 106 may be disposed between the first recesses 122 in the vertical direction. The first insulation layer 106 exposed by the sidewall of the first holes 120 may laterally protrude from the first sacrificial layers 104.

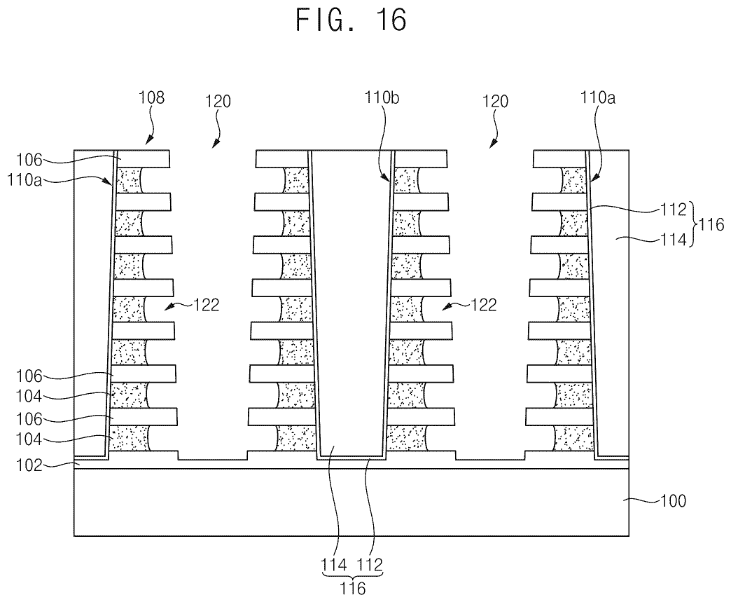

Referring to FIG. 17, a channel layer 130 may be conformally formed on an upper surface of the first mold layer pattern 108, the sidewall and bottom of the first holes 120, and the first sacrificial layer structures 116. The channel layer 130 may be formed to at least partially fill the first recesses 122.

In example embodiments, the channel layer 130 may include polysilicon. In some example embodiments, the channel layer 130 may include an oxide semiconductor layer.

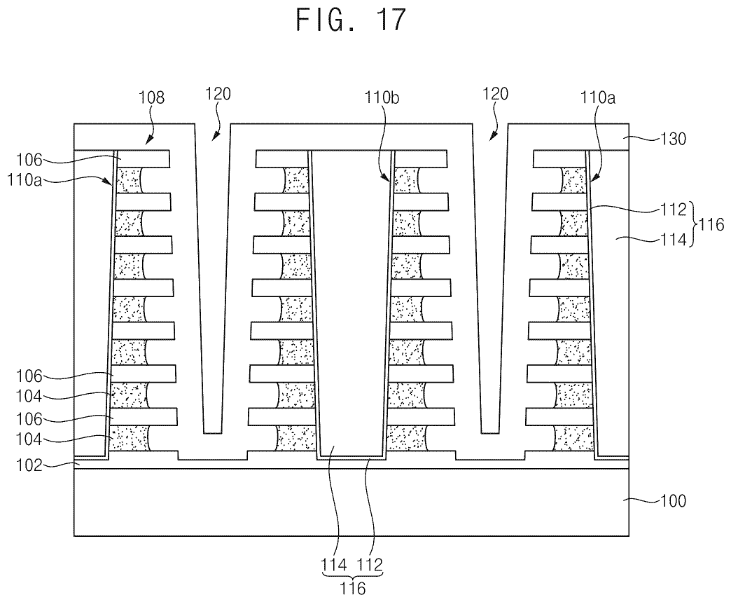

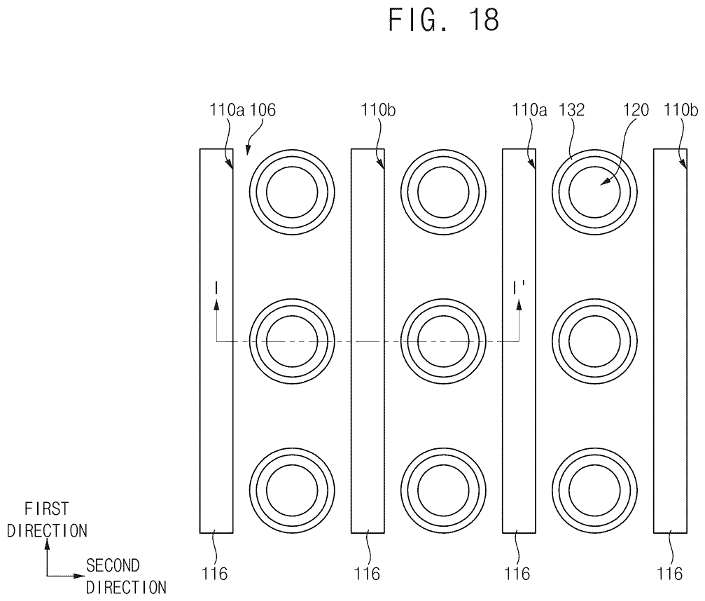

Referring to FIGS. 18 and 19, a portion of the channel layer 130 may be etched so that the channel layer 130 remains only inside the first recesses 122 by an isotropic etching process. In the etching process, the channel layer 130 disposed on the upper surface of the first mold layer pattern 108, the sidewall of the first insulation layers 106 in the first hole 120, a bottom of the first hole 120, and the sacrificial layer structure 116 may be removed to form channel patterns 132. Accordingly, the channel patterns 132 may be disposed in the first recesses 122, and may be spaced apart in the vertical direction (by the first insulation layers 106). The channel patterns 132 may be formed on the first sacrificial layers 104 exposed by the sidewall of the first hole 120. In the plan view, each of the channel patterns 132 may have a ring shape.

After forming the channel patterns 132, an internal space of each of the first recesses 122 may remain. Each of the channel patterns 132 may partially fill the first recess 122.

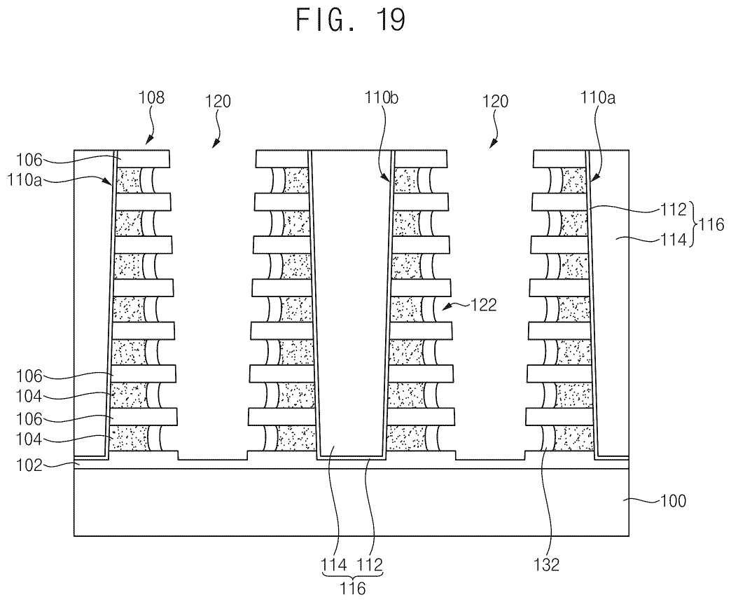

Referring to FIG. 20, an interface insulation layer 138 may be conformally formed on the upper surface of the first mold layer pattern 108, the first insulation layer 106, the channel pattern 132 and the lower etch stop layer 102 on the sidewall and bottom of the first hole 120, and the first sacrificial layer structure 116. The interface insulation layer 138 may include, e.g., silicon oxide or metal oxide. After forming the interface insulation layer 138, an internal space of each of the first recesses 122 may remain.

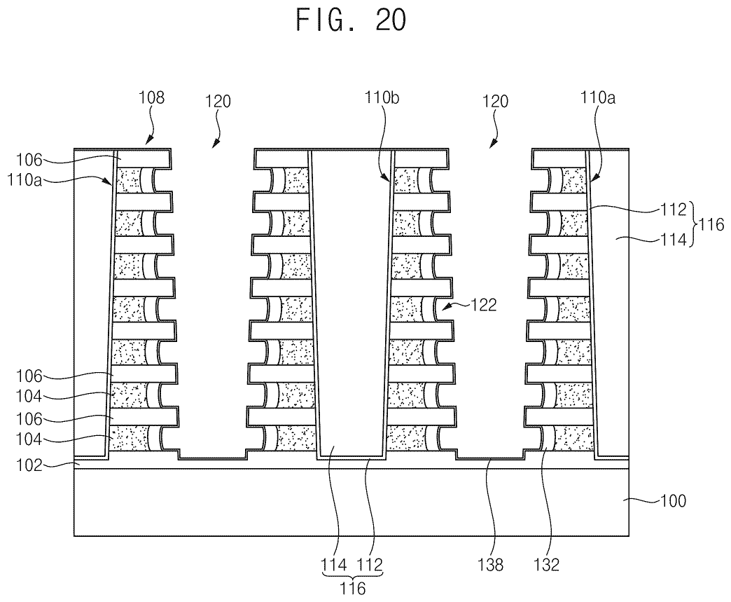

Referring to FIG. 21, a floating gate electrode layer 140 may be conformally formed on the interface insulation layer 138.

The floating gate electrode layer 140 may be formed on the sidewall and bottom of the first hole 120, the upper surface of the first mold layer pattern 108, and the first sacrificial layer structure 116. The floating gate electrode layer 140 may fill at least the first recess 122.

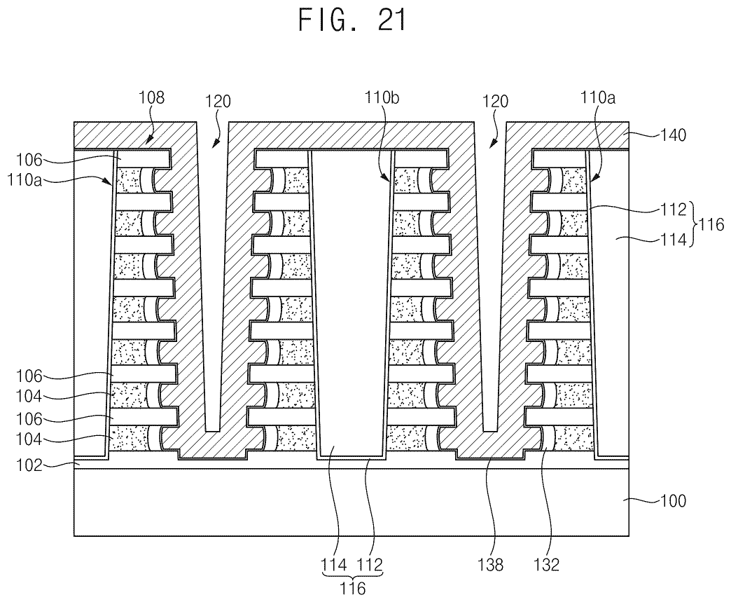

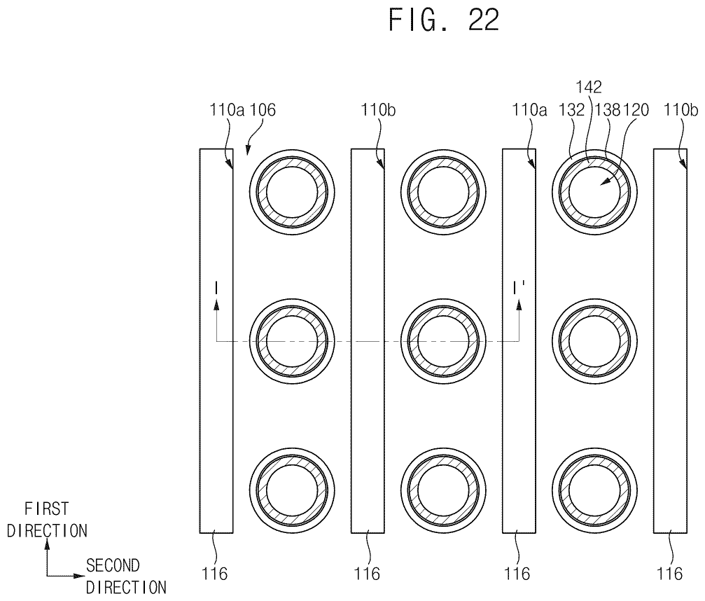

Referring to FIGS. 22 and 23, a portion of the floating gate electrode layer 140 (see FIG. 21) may be etched so that a portion of the floating gate electrode layer 140 remains inside the first recesses 122 by an isotropic etching process.

In the etching process, the floating gate electrode layer 140 disposed on the upper surface of the first mold layer pattern 108, the sidewall of the first insulation layer 106 in the first hole 120, the bottom of the first hole 120, and the first sacrificial layer structure 116 may be removed to form floating gate electrodes 142. The floating gate electrodes 142 may be formed in the first recesses 122, and may be spaced apart in the vertical direction. The floating gate electrodes 142 may be formed on the interface insulation layer 138 in the first recesses 122.

Each of the floating gate electrodes 142 may face the channel pattern 132 in the lateral direction. In the plan view, each of the floating gate electrodes 142 may have a ring shape.

In some example embodiments, the processes for forming the floating gate electrodes 142 on the interface insulation layer 138 may not be performed. The processes described with reference to FIGS. 20 and 21 may not be performed. In this case, the vertical semiconductor device shown in FIGS. 8 to 10 may be manufactured by performing subsequent processes.

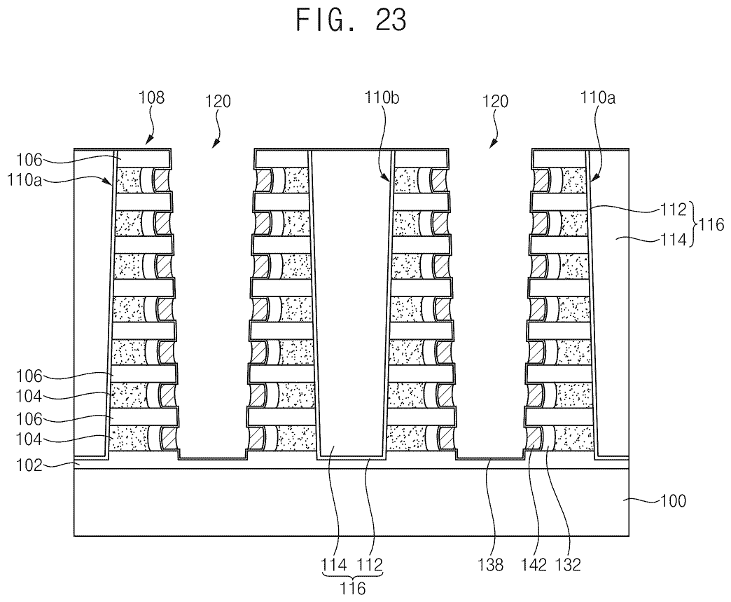

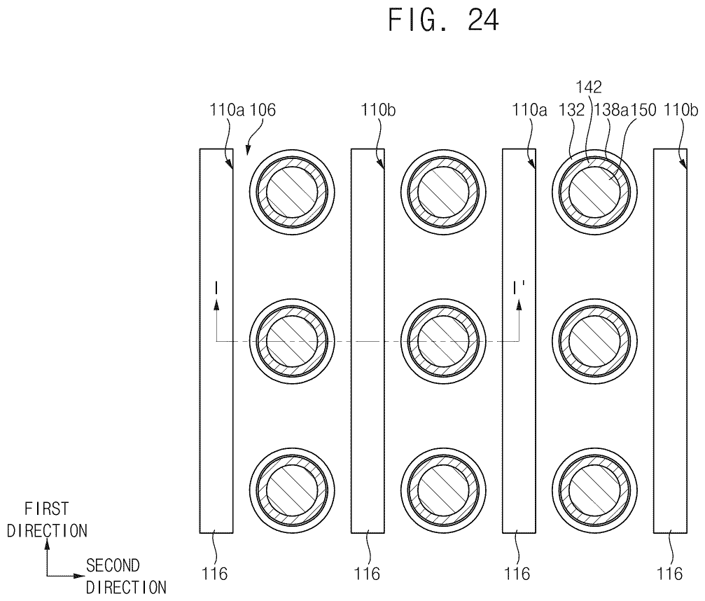

Referring to FIGS. 24 and 25, a second sacrificial layer structure 150 may be formed to at least partially fill the first hole 120. The second sacrificial layer structure 150 may include, e.g., silicon oxide. The second sacrificial layer structure 150 may contact the first insulation layers 106 and the floating gate electrodes 142 in the first hole 120.

In example embodiments, a third sacrificial layer may be formed on the first mold layer pattern 108 and the first sacrificial layer structure 116 to at least partially fill the first hole 120. The third sacrificial layer may be planarized until the upper surface of the first mold layer pattern 108 is exposed to form the second sacrificial layer structure 150. In the planarization process, the interface insulation layer on the first mold layer pattern 108 may be removed together to form an interface insulation layer pattern 138a.

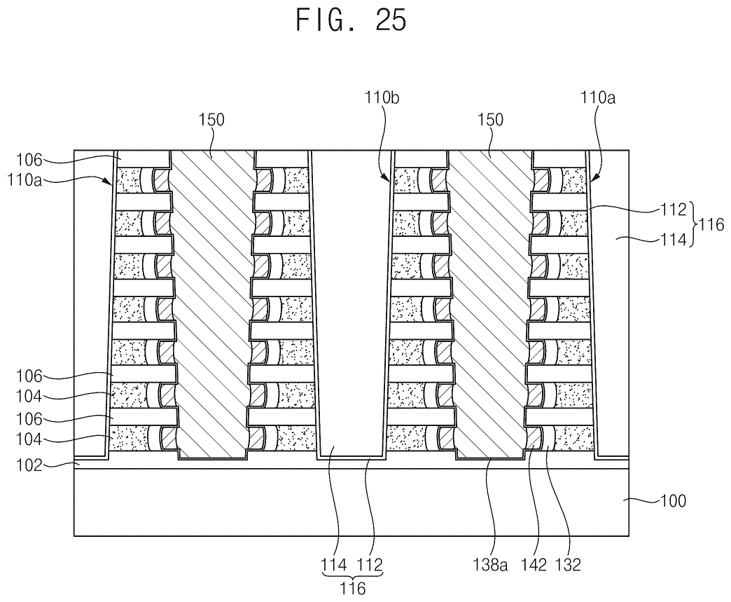

Referring to FIGS. 26 and 27, the first sacrificial layer structure 116 may be removed. The first sacrificial layer structure 116 may be removed by an isotropic etching process. Accordingly, inner spaces of the first and second trenches 110a and 110b may be formed again. The first mold layer pattern 108 may be exposed by the sidewalls of the first and second trenches 110a and 110b.

A portion of the first sacrificial layer 104 in the first mold layer pattern 108 (see FIG. 23) exposed by the sidewalls of the first and second trenches 110a and 110b may be removed to form second recesses 152 laterally connected with the first trench 110a and third recesses 154 laterally connected with the second trench 110b. The removal process of the portion of the first sacrificial layer 104 may include an isotropic etching process.

The second recess 152 may extend in the first direction. A portion of the outer wall of the channel pattern 132 may be exposed by the second recess 152. The third recess 154 may extend in the first direction. A portion of the outer wall of the channel pattern 132 may be exposed by the third recess 154.

The second and third recesses 152 and 154 may face each other with the first holes 120 (see FIG. 23) arranged in the first direction interposed therebetween. The second and third recesses 152 and 154 may not be connected with each other. That is, the first mold layer pattern 108 (referred to FIG. 2B) may remain on a region between the second recess 152 and the third recess 154 where holes are not formed.

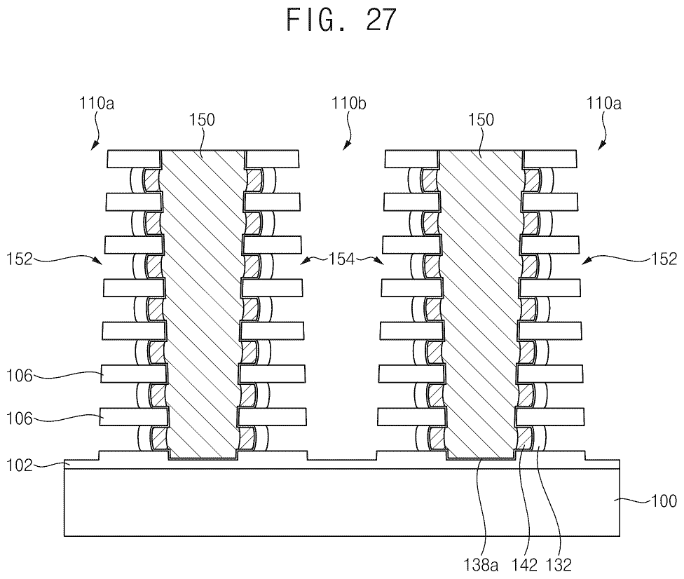

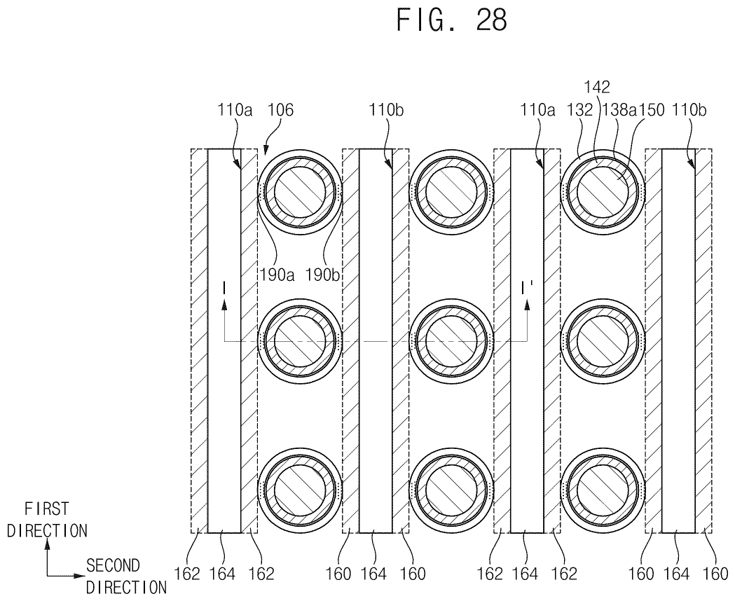

Referring to FIGS. 28 and 29, the channel pattern 132 exposed by the first and second trenches 110a and 110b and the second and third recesses 152 and 154 may be doped with N-type impurities or P-type impurities. The impurities may be doped in a portion of the channel pattern 132 contacting a source line subsequently formed and a portion of the channel pattern contacting a bit line subsequently formed. Accordingly, a first impurity region 190a may be formed at a first portion of the channel pattern 132 exposed by the second recess 152, and a second impurity region 190b may be formed at a second portion of the channel pattern 132 exposed by the third recess 154.

A first conductive layer may be formed on the first mold layer pattern 108 and the first and second sacrificial layer structures 116 and 150. The first conductive layer may be conformally formed on surfaces of the first and second trenches 110a and 110b and the second and third recesses 152 and 154. The first conductive layer may be formed to completely fill at least the second and third recesses 152 and 154. In example embodiments, the first conductive layer may include a metal. The first conductive layer may include, e.g., tungsten, titanium, or titanium nitride.

Thereafter, the first conductive layer may be isotropically etched so that the first conductive layer remains only inside the second and third recesses 152 and 154. In the etching process, the first conductive layer disposed on the upper surface of the first mold layer pattern 108, the sidewalls of the first insulation layer 106 in the first and second trenches 110a and 110b, the bottom of the first and second trenches 110a, the first conductive layer and the first and second sacrificial layer structures 116 and 150 may be removed to form bit lines in the third recesses and first conductive patterns in the second recesses. Each of the bit lines 160 may contact the outer sidewalls of the channel patterns 132 in the third recesses 154.

The third recesses 154 may be formed at both sidewalls of the second trench 110b in the second direction, so that the bit lines 160 may be formed on both sidewalls of the second trench 110b in the second direction, respectively. Additionally, an internal space may remain between the bit lines 160 within the second trench 110b.

Thereafter, the first insulation structure 164 may be formed to at least partially fill the second trench 110b between the bit lines 160. The first insulation structure 164 may extend in the first direction. The bit lines 160 facing each other in the second direction may be insulated from each other by the first insulation structure 164. Additionally, the first insulation structure 164 may be formed between the first conductive patterns 162.

In example embodiments, the first insulation structure 164 may include silicon oxide. In some example embodiments, the first insulation structure 164 may include a low-K material having a dielectric constant lower than a dielectric constant of silicon oxide. In some example embodiments, as shown in FIG. 7, an air tunnel 194 or a void may be included inside the first insulation structure 164.

The bit lines 160 may be spaced apart from each other in the vertical direction. The bit line 160 may extend in the first direction while electrically connecting to channel patterns 132 arranged in the first direction at each of a plurality of different vertical levels relative to the upper surface of the substrate 100. Meanwhile, the bit line 160 may not be connected to the channel patterns 132 arranged in the second direction. The bit line 160 may contact the second impurity region 190b.

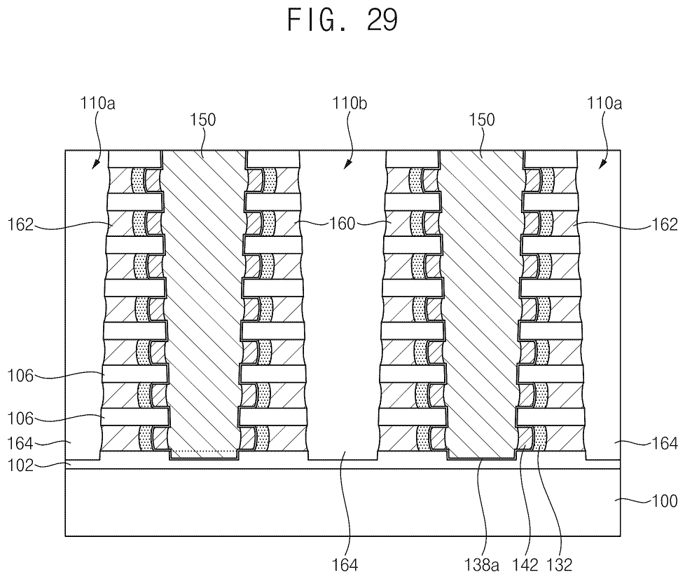

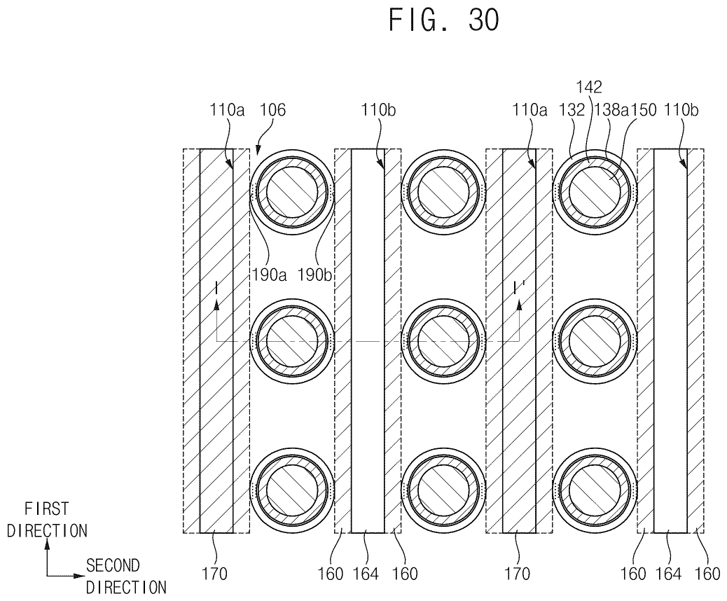

Referring to FIGS. 30 and 31, the first insulation structure 164 between the first conductive patterns 162 may be removed to form the first trench 110a.

Thereafter, a second conductive layer may be formed on the first mold layer pattern 108 and the second sacrificial layer structure 150 to at least partially fill the first trench 110a. The second conductive layer may include a metal. The second conductive layer may include, e.g., tungsten, titanium, or titanium nitride. In example embodiments, the second conductive layer may include a material the same as a material of the first conductive layer.

Thereafter, the second conductive layer may be planarized until the upper surface of the first mold layer pattern 108 is exposed to form a second conductive pattern 168. The second conductive pattern 168 may be formed to at least partially fill the first trench 110a, and may contact the first conductive pattern 162. The first and second conductive patterns 162 and 168 may serve as a source line 170.

In example embodiments, the first and second conductive patterns 162 and 168 may not be distinguished from each other, and may be formed as one conductive pattern. In some example embodiments, the first and second conductive patterns 162 and 168 may include different conductive materials. In the following drawings, the first conductive pattern 162 and the second conductive pattern 168 may be merged into one conductive pattern. The conductive pattern may be referred to as the source line 170. The source line 170 may contact the first impurity region 190a.

The processes for forming the bit line 160, the first insulation structure 164, and the source line 170 may not be limited to those described with reference to FIGS. 28 to 31.

In some example embodiments, a sacrificial pattern may be formed to fill the first trench 110a and the second recesses 152. The bit line 160 and the first insulation structure 164 may be formed in the second trench 110b and the third recesses 154. Thereafter, the sacrificial pattern in the first trench 110a and the second recesses 152 may be removed, and the source line 170 filling the first trench 110a and the second recesses 152 may be formed. As such, the bit line 160 and source line 170 may be formed by different deposition processes.

The source line 170 may extend in the vertical direction from the lower etch stop layer 102. Additionally, the source line 170 may extend in the first direction.

The source line 170 may contact the outer walls of the channel patterns 132 in the memory cells at each of the plurality of different vertical levels. Additionally, the source line 170 may extend in the first direction while contacting the portions of the outer walls of the channel patterns 132 spaced apart from each other in the first direction. Accordingly, the source line 170 may be electrically connected to the channel patterns 132 in memory cells at different vertical levels, and channel patterns 132 in memory cells spaced apart from each other in the first direction. The source line 170 may serve a common source of the channel patterns. In example embodiments, all channel patterns 132 between the second trenches 110b may be electrically connected to the source line 170 between the second trenches 110b.

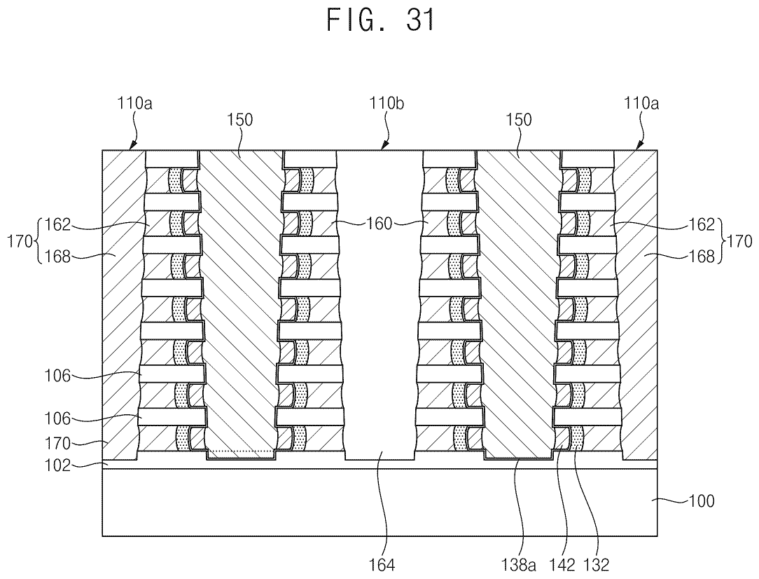

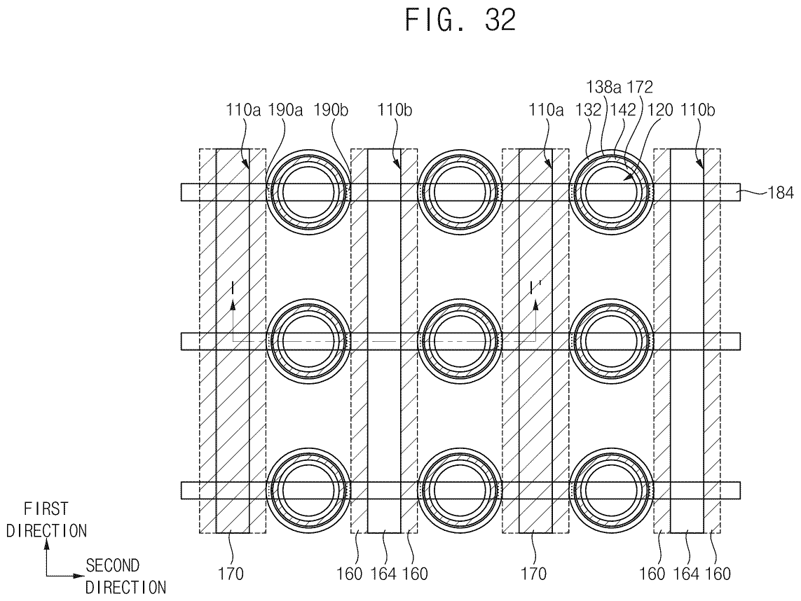

Referring to FIGS. 32 and 33, the second sacrificial layer structure 150 may be removed to form the first holes 120 again.

The floating gate electrodes 142 and the interface insulation layer pattern 138a on the first insulation layer 106 may be exposed by the sidewalls of the first holes 120.

A ferroelectric layer 172 may be conformally formed on upper surfaces of the first mold layer pattern 108, the source line 170, and the first insulation structure 164, and the sidewalls and bottom of the first hole 120.

In example embodiments, grooves 173 may be formed on a surface of the ferroelectric layer 172 at respective vertical levels corresponding to the first recess 122 (referred to FIG. 16). In some example embodiments, as shown in FIG. 5, the grooves 173 may not be formed on the surface of the ferroelectric layer 172 at respective vertical levels corresponding to the first recess 122.

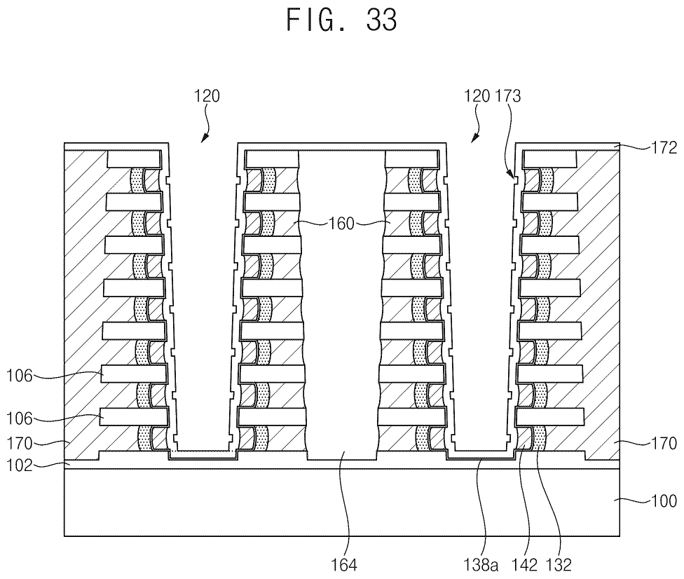

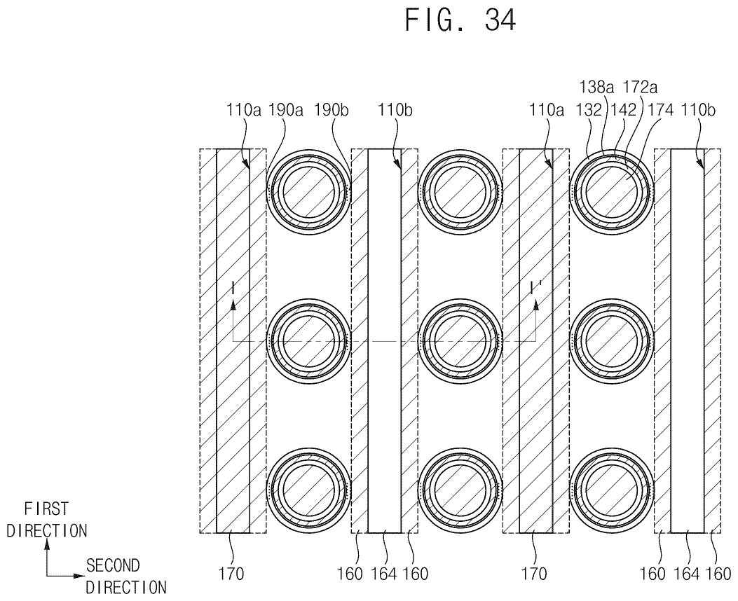

Referring to FIGS. 34 and 35, a third conductive layer may be formed on the ferroelectric layer 172 to at least partially fill the first holes 120. Thereafter, the third conductive layer and the ferroelectric layer 172 may be planarized until the first mold layer pattern 108 is exposed to form an interface insulation layer pattern 138a, a ferroelectric layer pattern 172a, and a word line 174 in each of the first holes 120.

The third conductive layer may include a metal.

Referring again to FIGS. 1, 2A, and 2B, a first upper insulating interlayer 180 may be formed on the word line 174, the ferroelectric layer pattern 172a, the interface insulation layer pattern, the first mold layer pattern 108, the source line 170, and the first insulation structure 164.

A contact plug 182 may be formed through the first upper insulating interlayer 180, and may contact an upper surface of the word line 174. A first conductive line 184 extending in the second direction may be formed on the first upper insulating interlayer 180 and the contact plug 182.

In example embodiments, the first conductive line 184 may be electrically connected to the plurality of word lines 174 arranged in the second direction.

By performing the above process, a vertical semiconductor device may be manufactured.

The vertical semiconductor device may be operated as follows.

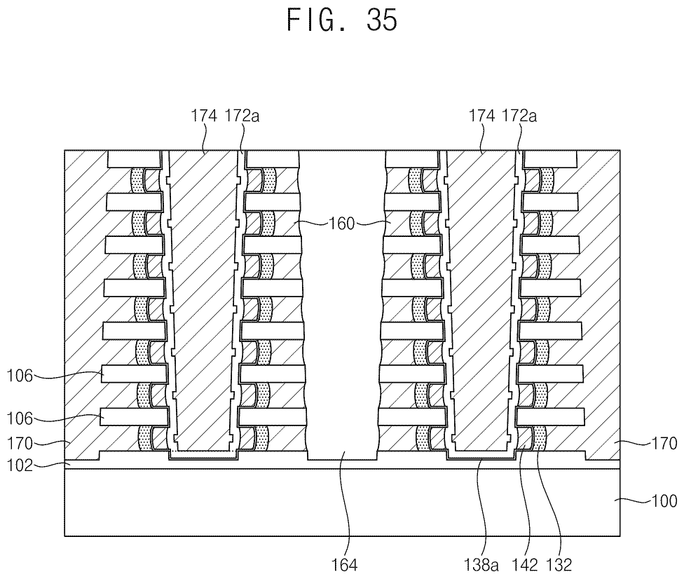

FIG. 36 is a graph showing an operation of the memory cell of the vertical semiconductor device according to one or more embodiments. Table 1 shows certain voltages during a write operation, and Table 2 shows certain voltages during a read operation.

Referring to Table 1 and FIG. 36, in a write operation, a write voltage may be applied to a selected word line, and a pass voltage may be applied to unselected word lines. The pass voltage may be a voltage that turns off regardless of data stored in the memory cell. 0V (e.g., ground level) may be applied to a selected bit line, and a power supply voltage may be applied to unselected bit lines. The power supply voltage may be applied to the source line. In this case, data 0 or data 1 may be written in the selected memory cell according to the write voltage. When data 0 is written in the memory cell, the memory cell may have a threshold voltage higher than a reference threshold voltage, and when data 1 is written into the memory cell, the memory cell may have a threshold voltage lower than the reference threshold voltage.

TABLE 1

| a write operation | voltage |
|---|---|
| selected word line | write voltage (Vwrite D0 or Vwrite D1) |
| unselected word lines | pass voltage (Vpass) |
| selected bit line | 0 V |
| unselected bit lines | power supply voltage (Vcc) |
| source line | power supply voltage (Vcc) |

Referring to Table 2 and FIG. 36, for a read operation, a read voltage may be applied to the selected word line, and the pass voltage may be applied to the unselected word line. A power supply voltage may be applied to the source line. The read voltage may be a verifying voltage (Vverify) to distinguish data in the memory cell, and may be a voltage a between the threshold voltage of the memory cell in which data 1 is written and the threshold voltage of the memory cell in which data 0 is written. In this case, the data written in the selected memory cell may be read by detecting drain currents of the selected memory cell.

TABLE 2

| a read operation | voltage |
|---|---|
| selected word line | read voltage (Vread) |
| unselected word lines | pass voltage (Vpass) |
| source line | power supply voltage (Vcc) |

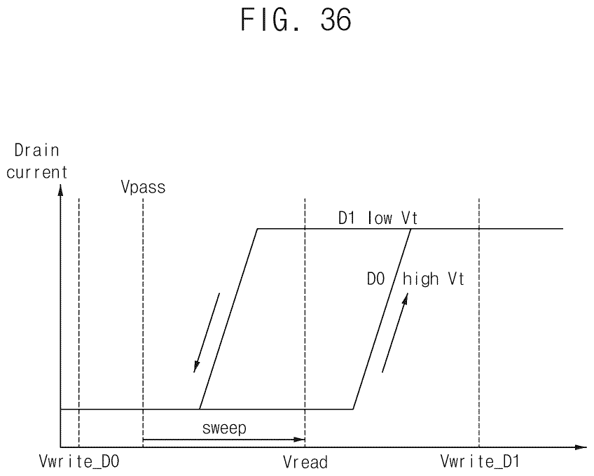

FIG. 37 is a plan view schematically illustrating wiring connected to the word lines in the vertical semiconductor device according to example embodiments.

Referring to FIG. 37, each of the word lines 174a and 174b may have a pillar shape extending in the vertical direction. The word lines 174a and 174b may be spaced apart in each of the first and second directions. The conductive lines 184a and 184b may be electrically connected to the word lines 174a and 174b arranged in the second direction. In example embodiments, the word lines arranged in the second direction may be referred to as a word line column, and a plurality of conductive lines 184a and 184b may be disposed on one word line column.

For example, as shown in FIG. 37, two conductive lines 184a and 184b may be disposed on the one word line column, and the two conductive lines 184a and 184b are referred to as a first conductive line 184a and a second conductive line 184b, respectively. Two word lines disposed between the two bit lines 160 spaced apart in the second direction are referred to as first and second word lines 174a and 174b, respectively. The first word lines 174a may be electrically connected to the first conductive lines 184a, and the second word lines 174b may be electrically connected to the second conductive lines 184b. In the one word line column, the first word line 174a may contact a first contact plug 182a, and may be connected to the first conductive line 184a via the first contact plug 182a. In the one word line row, the second word line 174b may contact a second contact plug 182b, and may be connected to the second conductive line 184b via the second contact plug 182b.

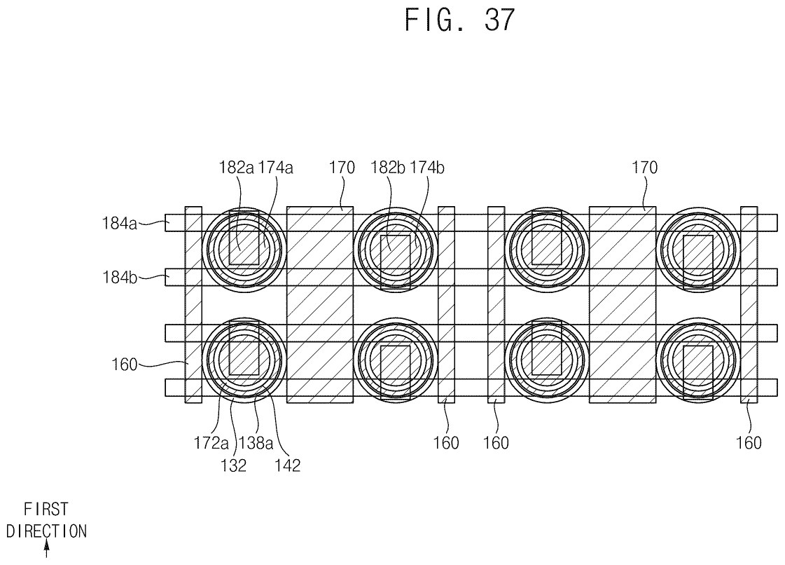

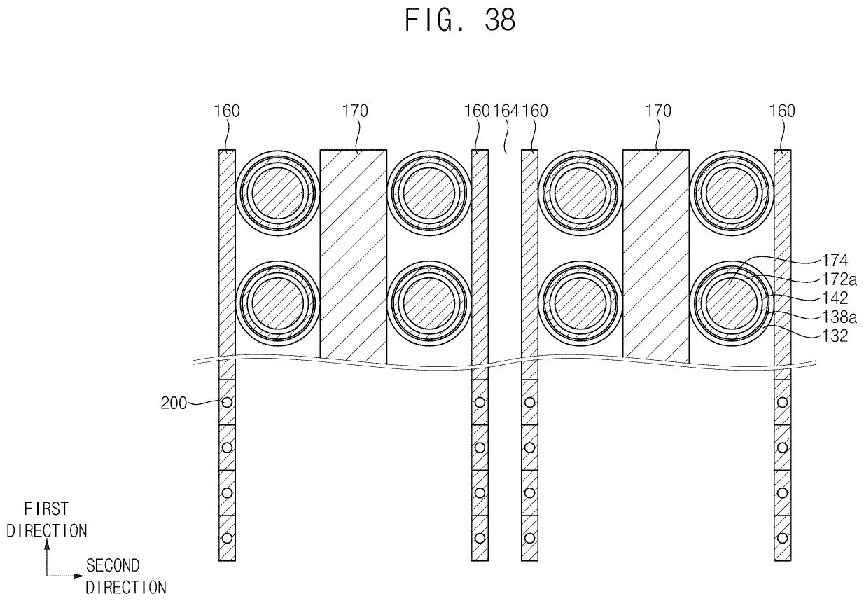

FIGS. 38 and 39 are a plan view and a cross-sectional view, respectively, schematically illustrating an end of the bit line and a shape of a wiring in the vertical semiconductor device according to example embodiments.

Referring to FIGS. 38 and 39, the bit lines 160 may be spaced apart in the vertical direction, and each of the bit lines 160 may extend in the first direction. Accordingly, end portions of the bit lines 160 in the first direction may have a structure in which electrical signals can be applied to each of the bit lines 160. For example, bit line contact plugs 200 for applying electrical signals may be disposed on the end portions of the bit lines 160, respectively.

Upper surfaces of the end portions of bit lines 160 may be exposed. In example embodiments, the end portions of the bit lines 160 may have a step shape. For example, the end portions of the bit lines 160 may have a step shape in each of the first direction and the second direction. For example, as shown in FIG. 38, the end portions of the bit lines 160 may have a step shape only in the first direction. However, the step shape of the end portions of the bit lines 160 may not be limited thereto.

The bit line contact plugs 200 may contact the upper surfaces of the end portions of the bit lines 160, respectively. Bit line wiring (not shown) electrically connected to each of the bit line contact plugs 200 may be further formed on the bit line contact plugs 200. The bit line contact plugs 200 may pass through the first upper insulating interlayer 180 (referred to FIG. 1).

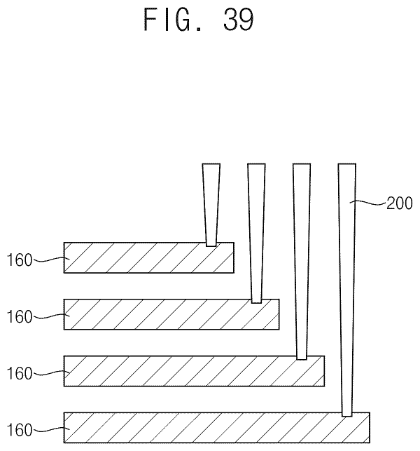

FIG. 40 is a cross-sectional view schematically illustrating an arrangement of peripheral circuits in a vertical semiconductor device according to example embodiments.

Referring to FIG. 40, the vertical semiconductor device may include a memory cell structure 220 including memory cells according to one of the above embodiments.

The memory cell structure 220 may be disposed on the peripheral circuits 210 for driving the memory cell structure 220. The vertical semiconductor device may have a COP (cell over peripheral) structure.

The peripheral circuits 210 may be disposed on a substrate 100. The peripheral circuits may include transistors, resistor structures, capacitors, wiring, etc. First and second lower insulating interlayers 212 and 214 may be formed on the substrate 100 to cover the peripheral circuits. The term “cover” (or “covering,” “covers,” or like terms), as may be used herein, is intended to broadly refer to an element, structure or layer that is on or over another element, structure or layer, either directly or with one or more other intervening elements, structures or layers therebetween.

The memory cell structure 220 may be disposed on the second lower insulating interlayer 214. The peripheral circuits may be disposed below the first mold layer pattern and the word lines included in the memory cell structure 220.

A first upper insulating interlayer 222 may cover the memory cell structure 220. Upper contact plugs 224 may pass through at least the first upper insulating interlayer 222 in the vertical direction, and may be electrically connected to the memory cell structure 220 and the peripheral circuits 210. In example embodiments, the upper contact plugs 224 may be electrically connected to the bit line, the word line, and the source line in the memory cell structure 220. Additionally, the upper contact plugs 224 may be electrically connected to wirings included in the peripheral circuits 210.

A second upper insulating interlayer 230 may be formed on the first upper insulating interlayer 222. Upper wirings 232 may pass through the second upper insulating interlayer 230, and may be electrically connected to the upper contact plugs 224.

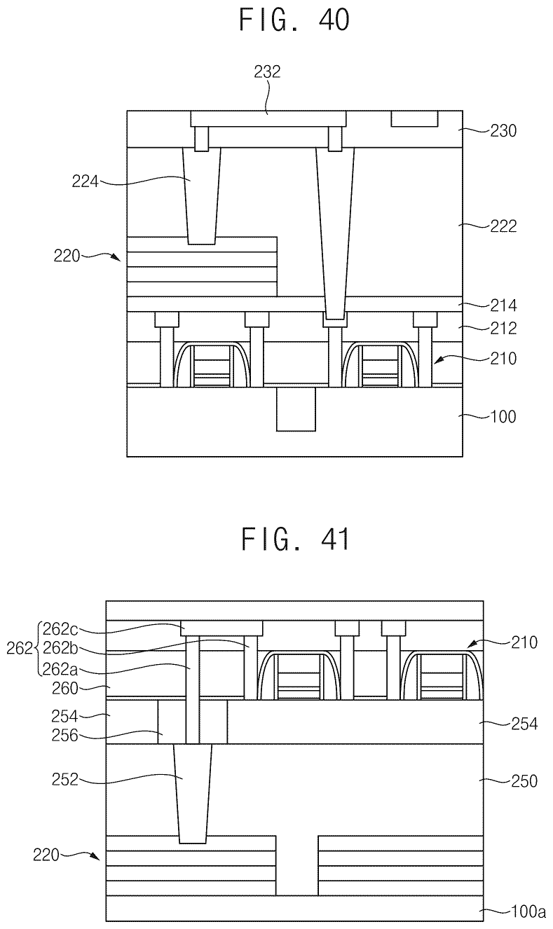

FIG. 41 is a cross-sectional view schematically illustrating an arrangement of peripheral circuits in a vertical semiconductor device according to example embodiments.

Referring to FIG. 41, the vertical semiconductor device may include a memory cell structure 220 including memory cells according to one of the above embodiments.

The memory cell structure 220 may be disposed below the peripheral circuits for driving the memory cell structure. The vertical semiconductor device may have the POC (peripheral over cell) structure. The vertical semiconductor device includes two substrates 100a and 254. In manufacturing of the vertical semiconductor device, a bonding process of the substrates 100a, 254 may be performed.

The memory cell structures 220 may be disposed on a first substrate 100a. A lower insulating interlayer 250 may be disposed on the first substrate 100a to cover the memory cell structures 220. Lower contact plugs 252 may pass through the lower insulating interlayer 250, and may be electrically connected to the memory cell structure 220. In example embodiments, the lower contact plugs 252 may be electrically connected to the bit line, the word line, and the source line.

A second substrate 254 may be disposed on the lower insulating interlayer 250 and the lower contact plug 252. An insulation pattern 256 may pass through the second substrate 254.

Peripheral circuits 210 may be disposed on the second substrate 254 and the insulation pattern 256. The peripheral circuits 210 may include transistors, resistor structures, capacitors, wiring, etc. An upper insulating interlayer 260 may be disposed on the second substrate 254 to cover the peripheral circuits 210. The second substrate 254 and the peripheral circuits 210 may be disposed over the upper surface of the first mold layer pattern and word line in the memory cell structure 220.

Upper wirings 262 electrically connected to the lower contact plugs 252 and the peripheral circuits 210 may be disposed in the upper insulating interlayer 260 and the insulation pattern 256. The upper wirings 262 may include a first upper contact plug 262a passing through the upper insulating interlayer and the insulation pattern 256 and connecting the memory cell structure 220 via the lower contact plugs 252, a second upper contact plug 262b passing through the upper insulating interlayer 260 and connecting the peripheral circuits, and a connecting wiring 262c for electrically connecting the first and second upper contact plugs 262a and 262b.

The vertical semiconductor devices according to example embodiments may be used as memory devices included in electronic products such as mobile devices, memory cards, and computers.

While the present inventive concepts have been shown and described with reference to example embodiments thereof, it will be understood by those of ordinary skill in the art that various changes in form and details may be made thereto without departing from the scope of the present inventive concepts as set forth by the following claims.

What is claimed is:

1. A vertical semiconductor device, comprising:
a word line having a pillar shape on a substrate, the word line extending in a vertical direction perpendicular to an upper surface of the substrate;
a ferroelectric layer pattern extending around a sidewall and bottom of the word line;
a memory layer including an interface insulation layer pattern and a channel pattern sequentially stacked on the ferroelectric layer pattern, each of the interface insulation layer pattern and the channel pattern having a ring shape extending around the sidewall of the word line;
a source line contacting a first portion of an outer wall of the channel pattern, the source line extending in a first direction parallel to the upper surface of the substrate; and
a bit line extending in the first direction, the bit line contacting a second portion of the outer wall of the channel pattern facing the first portion of the outer wall of the channel pattern.

2. The vertical semiconductor device of claim 1, wherein the memory layer includes a plurality of memory layers each having a respective interface insulation layer pattern and a respective channel pattern on an outer wall of the word line, and
the plurality of memory layers are spaced apart from each other in the vertical direction.

3. The vertical semiconductor device of claim 2, wherein a first insulation layer is between the memory layers in the vertical direction.

4. The vertical semiconductor device of claim 2, wherein the bit line includes a plurality of bit lines spaced apart from each other in the vertical direction, and
wherein each of the plurality of bit lines is electrically connected to the respective channel pattern at each of a plurality of vertical levels relative to the upper surface of the substrate.

5. The vertical semiconductor device of claim 4, wherein a first insulation layer is between the bit lines in the vertical direction.

6. The vertical semiconductor device of claim 2, wherein the source line extends in the vertical direction, and the source line is electrically connected to a plurality of the respective channel patterns spaced apart from each other in the vertical direction.

7. The vertical semiconductor device of claim 1, wherein the word line includes a plurality of word lines, and
wherein the plurality of word lines are spaced apart from each other in the first direction, and are spaced apart from each other in a second direction parallel to the upper surface of the substrate and perpendicular to the first direction.

8. The vertical semiconductor device of claim 7, wherein the bit line is electrically connected to channel patterns on at least a subset of the plurality of word lines arranged in the first direction.

9. The vertical semiconductor device of claim 7, wherein the source line is electrically connected to channel patterns on at least a subset of the plurality of word lines arranged in the first direction, and
wherein the source line contacts outer walls of channel patterns on a pair of adjacent word lines in the second direction.

10. The vertical semiconductor device of claim 1, wherein the channel pattern includes polysilicon, an oxide semiconductor, or a two-dimensional material.

11. The vertical semiconductor device of claim 1, further comprising a floating gate electrode having a ring shape between the ferroelectric layer pattern and the interface insulation layer pattern.

12. The vertical semiconductor device of claim 1, further comprising a mold layer pattern between a plurality of word lines spaced apart from each other in the first direction,
wherein the mold layer pattern includes sacrificial layers and insulation layers alternately stacked in the vertical direction.

13. The vertical semiconductor device of claim 1, wherein each of the first portion of the outer wall of the channel pattern and the second portion of the outer wall of the channel pattern includes an impurity region doped with an impurity.

14. A vertical semiconductor device, comprising:
a mold layer pattern on a substrate;
a plurality of word lines passing through the mold layer pattern, each of the plurality of word lines having a pillar shape extending in a vertical direction perpendicular to an upper surface of the substrate, and being arranged in each of a first direction and a second direction parallel to the upper surface of the substrate and perpendicular to each other;
a ferroelectric layer pattern extending around a sidewall and bottom of each of the plurality of word lines;
a plurality of memory layers on the ferroelectric layer pattern, each of the plurality of memory layers including a respective interface insulation layer pattern and a respective channel pattern having a ring shape extending around a sidewall of each of the plurality of word lines, and the plurality of memory layers being spaced apart from each other in the vertical direction;
a plurality of bit lines spaced apart from each other in the vertical direction, the plurality of bit lines being electrically connected to the respective channel patterns of the plurality of memory layers at corresponding vertical levels in the memory layers, relative to the upper surface of the substrate; and
a source line extending in the vertical direction, the source line being commonly connected to at least a subset of the channel patterns included in the plurality of memory layers arranged in the vertical direction, and being electrically connected to channel patterns arranged in the first direction, and the source line facing the plurality of bit lines in the second direction.

15. The vertical semiconductor device of claim 14, wherein the plurality of bit lines extend in the first direction, and end portions of the plurality of bit lines in the first direction have a step shape.

16. The vertical semiconductor device of claim 14, further comprising a floating gate electrode having a ring shape between the ferroelectric layer pattern and the interface insulation layer pattern of each of the plurality of memory layers.

17. The vertical semiconductor device of claim 14, further comprising peripheral circuits and a lower insulating interlayer on the substrate below the mold layer pattern and the plurality of word lines.

18. The vertical semiconductor device of claim 14, further comprising an upper substrate on the mold layer pattern and the plurality of word lines, and peripheral circuits on the upper substrate.

19. The vertical semiconductor device of claim 14, wherein the source line comprises at least a pair of adjacent source lines, and wherein two bit lines of the plurality of bit lines are between the pair of adjacent source lines in the second direction.

20. A vertical semiconductor device, comprising:
a word line having a pillar shape on a substrate;
a memory layer including a ferroelectric layer pattern, an interface insulation layer, and a channel pattern sequentially stacked on an outer wall of the word line;
a bit line extending in a horizontal direction parallel to an upper surface of the substrate and contacting an outer wall of the channel pattern;
a source line contacting the outer wall of the channel pattern, the source line extending in the horizontal direction, and the source line facing the bit line in the horizontal direction.
